(19) United States
(12) Patent Application Publication
(10) Pub. No.: US 2024/0192649 A1
(43) Pub. Date: Jun. 13, 2024

(54) CONTROL SYSTEM OF A FACILITY

(71) Applicant: View, Inc., Milpitas, CA (US)

(72) Inventors: Feliciano Vicente Gomez-Martinez, Los Gatos, CA (US); Sajith Kamalnath Gopinathanasari, Milpitas, CA (US); Jue Wang, San Jose, CA (US); Manoj Madan Kumar, Sunnyvale, CA (US); Nitesh Trikha, Pleasanton, CA (US); Aditya Dayal, Sunnyvale, CA (US); Ahmed Mustafa, Fremont, CA (US); Himay Rashmikant Shukla, Fremont, CA (US)

(21) Appl. No.: 18/285,846

(22) PCT Filed: Apr. 6, 2022
(86) PCT No.: PCT/US2022/023605

§ 371 Date: Oct. 5, 2023

Related U.S. Application Data
(60) Provisional application No. 63/171,871, filed on Apr. 7, 2021.

(51) Int. Cl. G05B 15/02; H04L 12/28

(52) U.S. Cl. CPC G05B 15/02; H04L 12/2818; G05B 2219/2642

(57) ABSTRACT

The present disclosure describes a facility (e.g., home) control system using a community of components (e.g., comprising one or more sensors, emitters and/or transceivers) that are configured to locate at least a portion of its members and control one or more devices of the facility.

### RELATED APPLICATIONS

This application claims priority from U.S. Provisional Patent Application Ser. No. 63/171,871, filed Apr. 7, 2021, titled, “CONTROL SYSTEM OF A FACILITY.” This application is related to International Patent Application Serial No. PCT/US21/012313, filed Jan. 6, 2021, titled “LOCALIZATION OF COMPONENTS IN A COMPONENT COMMUNITY,” that claims priority from U.S. Provisional Patent Application Ser. No. 63/133,725, filed Jan. 4, 2021, titled “LOCALIZATION OF COMPONENTS IN A COMPONENT COMMUNITY,” from U.S. Provisional Patent Application Ser. No. 62/958,653, filed Jan. 8, 2020, titled “Sensor Auto-location,” and from U.S. patent application Ser. No. 29/652,869, filed Dec. 22, 2020, titled “TRANSCEIVER TAG.” International Patent Application Serial No. PCT/US21/012313 is also a Continuation-in-Part of (I) U.S. patent application Ser. No. 16/696,887, filed Nov. 26, 2019, titled “MULTI-SENSOR DEVICE AND SYSTEM WITH A LIGHT DIFFUSING ELEMENT AROUND A PERIPHERY OF A RING OF PHOTOSENSORS AND AN INFRARED SENSOR,” that claims priority to U.S. patent application Ser. No. 15/287,646, filed Oct. 6, 2016, now U.S. Pat. No. 10,533,892, issued Jan. 14, 2020, titled “MULTI-SENSOR DEVICE AND SYSTEM WITH A LIGHT DIFFUSING ELEMENT AROUND A PERIPHERY OF A RING OF PHOTOSENSORS AND AN INFRARED SENSOR,” that is a Continuation of U.S. patent application Ser. No. 14/998,019, filed Oct. 6, 2015, now U.S. Pat. No. 10,690,540, issued Jun. 23, 2020, titled “MULTI-SENSOR HAVING A LIGHT DIFFUSING ELEMENT AROUND A PERIPHERY OF A RING OF PHOTOSENSORS,” (II) U.S. Patent Application Ser. No. 17/251,100, filed Dec. 10, 2020, titled “OPTICALLY SWITCHABLE WINDOWS FOR SELECTIVELY IMPEDING PROPAGATION OF LIGHT FROM AN ARTIFICIAL SOURCE,” that claims priority to U.S. patent application Ser. No. 16/099,424, filed Nov. 6, 2018, titled “WINDOW ANTENNAS,” that is a National Stage of International Patent Application Serial No. PCT/US17/31106, filed May 4, 2017, that claims priority to, e.g., U.S. Provisional Patent Application Ser. No. 62/379,163, filed Aug. 24, 2017, titled “WINDOW ANTENNAS,” to U.S. Provisional Patent Application Ser. No. 62/352,508, filed Jun. 20, 2016, titled “WINDOW ANTENNAS,” to U.S. Provisional Patent Application Ser. No. 62/340,936, filed May 24, 2016, titled “WINDOW ANTENNAS,” and to U.S. Provisional Patent Application Ser. No. 62/333,103, filed May 6, 2016, titled “WINDOW ANTENNAS,” (III) U.S. patent application Ser. No. 16/946,947, filed Jul. 13, 2020, titled “AUTOMATED COMMISSIONING OF CONTROLLERS IN A WINDOW NETWORK,” that is a Continuation of U.S. patent application Ser. No. 16/462,916, filed May 21, 2019, titled “AUTOMATED COMMISSIONING OF CONTROLLERS IN A WINDOW NETWORK,” that is a Continuation of U.S. patent application Ser. No. 16/082,793, filed Sep. 6, 2018, titled “METHOD OF COMMISSIONING ELECTROCHROMIC WINDOWS,” that is a National Stage of International Patent Application Serial No. PCT/US17/62634 filed Nov. 20, 2017, titled “AUTOMATED COMMISSIONING OF CONTROLLERS IN A WINDOW NETWORK,” that claims priority to, e.g., U.S. Provisional Patent Application Ser. No. 62/551,649, filed Aug. 29, 2017, titled “AUTOMATED COMMISSIONING OF CONTROLLERS IN A WINDOW NETWORK,” and to U.S. Provisional Patent Application Ser. No. 62/426,126, filed Nov. 23, 2016, titled “AUTOMATED COMMISSIONING OF CONTROLLERS IN A WINDOW NETWORK,” (IV) U.S. patent application Ser. No. 16/980,305, filed Sep. 11, 2020, titled “WIRELESSLY POWERED AND POWERING ELECTROCHROMIC WINDOWS,” that is a National Stage of International Patent Application Serial No. PCT/US19/22129 filed Mar. 13, 2019, titled “WIRELESSLY POWERED AND POWERING ELECTROCHROMIC WINDOWS,” that claims priority to U.S. Provisional Patent Application Ser. No. 62/642,478, filed Mar. 13, 2018, titled “WIRELESSLY POWERED AND POWERING ELECTROCHROMIC WINDOWS,” (V) U.S. patent application Ser. No. 15/727,258, filed Oct. 6, 2017 titled “COMMISSIONING WINDOW NETWORKS,” that claims priority to, e.g., U.S. Provisional Patent Application Ser. No. 62/551,649, filed Aug. 29, 2017, titled “AUTOMATED COMMISSIONING OF CONTROLLERS IN A WINDOW NETWORK,” and to U.S. Provisional Patent Application Ser. No. 62/426,126, filed Nov. 23, 2016, titled “AUTOMATED COMMISSIONING OF CONTROLLERS IN A WINDOW NETWORK,” and (VI) U.S. patent application Ser. No. 17/083,128, filed Oct. 28, 2020, titled “BUILDING NETWORK,” that is a Continuation of U.S. patent application Ser. No. 16/664,089, filed on Oct. 25, 2019, titled “BUILDING NETWORK,” that is a National Stage of International Patent Application Serial No. PCT/US18/29460, filed Apr. 25, 2018, titled “TINTABLE WINDOW SYSTEM FOR BUILDING SERVICES.” Each of the above patent documents is incorporated herein by reference in its entirety.

### BACKGROUND

A community of components may be placed at locations in an enclosure to analyze, detect and/or react to one or more of: data, temperature, humidity, sound, electromagnetic waves, position, distance, movement, speed, vibration, volatile compounds (VOCs), dust, light, glare, color, gases, and/or other aspects of the enclosure. A location of the component may be important to interpretation of the data it is connecting. A location of the component may be important to its calibration, replacement, maintenance, and/or repair. A lack of knowledge about a component's location, may make its calibration, replacement, maintenance, and/or repair difficult to perform. After placement of a community of components, locations of one or more of the components may be forgotten and/or may change. The location of the component may be determined and/or verified externally, e.g., by a person. The external localization of the component (e.g., transceiver and/or sensor) may be labor intensive, time consuming, and/or prone to (e.g., human) errors.

The current technology relies on a first component (e.g., sensor) having proximity to a second component being tracked (e.g., when communicating via Bluetooth). This may preclude a user from distant from a stationary component from tracking the second component (e.g., when a user is away from home, or the user left a device a different location). The tracking may rely on acoustic signaling (e.g., a sound) so that a user can find the tracked component when it is misplaced, e.g., using hearing (which may be a problem for deaf people, people in a noisy environment, or when the tracked component is out of hearing range). The tracked component is a component that should be localized.

### SUMMARY

Various aspects disclosed herein alleviate at least in part one or more shortcomings related to localization of one or more components within an enclosure. Various aspects disclosed herein may relate to a community (e.g., assembly, group, and/or network) of components configured to analyze, detect and/or react to one or more of the characteristics of the enclosure. The components may be configured to react to various signals. The signals may comprise data (e.g., received). The signals may comprise a (e.g., digital) signal.

In various aspects disclosed herein, components in a facility are connected to a network and to an application having a graphical user interface (GUI). The component may include one or more devices enabling geo-location technology (e.g., including a transceiver such as a UWB radio) that are operatively coupled to a network. Such network may facilitate localization of other (e.g., transitory and/or stationary) components, e.g., in conjunction with the GUI application. By using the application in conjunction with other local networked components (e.g., device ensembles), location of the other components may be achieved. The localization process may (i) require requiring the user to be at the local of the other component and/or (ii) provide input. At times, the user may provide input without being at the facility (e.g., while being located remote from the facility). Such location method may be done remotely, automatically, and/or may not rely on sound detection. Localization of the components may facilitate control of other device(s) operatively couped to the network. The other device may be utilized to control the environment of the facility. The other components may provide an optimal environment for the user (e.g., in terms of user request(s), optimal health, safety, aesthetic, comfort, inventory, and/or otherwise offer a delightful environment). The other components may aid in health and/or safety of the user. The other components may aid in health and/or safety of the facility, e.g., with respect to the user.

In another aspect, a method of locating a plurality of stationary components in a facility, the method comprises: (a) initiating at least three of the stationary components at separate locations of the facility; and (b) performing a procedure, including: (i) activating an application configured to receive input, (ii) requesting input of a location of each of the at least three stationary components, and (iii) storing the location for each of the at least three stationary components in a database.

In some embodiments, the method further comprises determining positions of other stationary components of the facility that are other than the at least three stationary components at least in part by determining relative distances of the other stationary components to the at least three stationary components. In some embodiments, determining relative distances of the other stationary components to the at least three stationary components comprise (i) transmitting a signal from the at least three stationary components, which signal is received by the other stationary components, and (ii) using the signal to calculate relative positions between the at least three stationary components and the other stationary components. In some embodiments, determining the relative distances of the other stationary components to the at least three stationary components comprise determining the relative distances of the other stationary components relative to each of the at least three stationary components. In some embodiments, determining the positions of the other stationary components comprises determining the positions of the other stationary components relative to each of the at least three stationary components. In some embodiments, the application configured to receive the input comprises a non-transitory computer readable program instructions configured to be read by one or more processors. In some embodiments, the program instructions are embedded in a medium or in media. In some embodiments, the one or more processors comprise circuitry. In some embodiments, the one or more processors are included in a mobile device. In some embodiments, the mobile device comprises a cellular phone, a laptop computer, a pad or an identification tag. In some embodiments, requesting input of the location of the at least three stationary components includes inputting the location on a map of at least a portion of the facility. In some embodiments, the map comprises a building information modelling (BIM) file. In some embodiments, the map comprises an architectural plan. In some embodiments, the map comprises a home blueprint file. In some embodiments, the map comprises a three-dimensional home file. In some embodiments, the map comprises a plan view of a room layout of a home. In some embodiments, the facility comprises a home. In some embodiments, the facility comprises a private house. In some embodiments, the private house comprises an apartment in a multi-unit apartment building. In some embodiments, the private house comprises a single family house or is a townhouse. In some embodiments, the at least three of the stationary components initiated are attached to, or embedded in, one or more fixtures of the facility. In some embodiments, the one or more fixtures comprise a framing. In some embodiments, the one or more fixtures comprise a window framing. In some embodiments, the one or more fixtures comprise a mullion, a transom, a wall, a ceiling or a floor. In some embodiments, a stationary component of the plurality of stationary components comprises a sensor, an emitter, or a transceiver. In some embodiments, a stationary component of the plurality of stationary components is included in a device ensemble. In some embodiments, the device ensemble comprises (i) sensors or (ii) a sensor and an emitter. In some embodiments, a stationary component of the plurality of stationary components comprises geo-location technology. In some embodiments, the geo-location technology comprises a global positioning system (GPS). In some embodiments, the geo-location technology comprises ultra-wideband. In some embodiments, the geo-location technology comprises a wireless personal area network technology. In some embodiments, the wireless personal area network technology comprises a range of at most about 100 meters, a transmit power of from about 10 Watts to about 100 Watts, a frequency range of from about 2400 Mega Hertz (MHz) to about 2483.5 Mega Hertz, a data rate of from about 0.125 Megabits per second to about 2 Megabits per second (Mb/s), or any combination thereof. In some embodiments, an input of the location, for each of the at least three stationary components in response to a request for the input of the location, is a manual input. In some embodiments, the application configured to receive the input is configured to recognize a human input of the location. In some embodiments, the plurality of stationary components and the application configured to receive the input are operatively coupled to a network of the facility, which network is configured to facilitate controlling one or more devices of the facility. In some embodiments, the plurality of stationary components and the application configured to receive the input are operatively coupled to a control system of the facility, which control system is configured to facilitate controlling one or more devices of the facility. In some embodiments, the control system comprises a building management system (BMS). In some embodiments, (i) the plurality of stationary components and (ii) the application configured to receive the input, are operatively coupled to a network of the facility, which network is configured to facilitate controlling one or more devices of the facility. In some embodiments, the one or more devices comprise a refrigerator, a stove, an oven, a microwave oven, a toaster, an air fryer, a vacuum cleaner system, a washing machine, a clothes dryer, a dish washer, a food processor, a media player, a media screen, a radio, a music player, a heater, a cooler, a ventilator, lighting, a safety related device, a health related device, a tintable window, an automatic door, or a heating, ventilation and air conditioning (HVAC) system. In some embodiments, the tintable window is an electrochromic window.

In another aspect, a non-transitory computer program instructions for locating a plurality of stationary components in a facility, the non-transitory computer program instructions, when read by one or more processors, causes the one or more processors to execute, or direct execution of, one or more operations of any of the methods disclosed above. In some embodiments, the program instructions are embedded in at least one program product. In some embodiments, the program instructions are embedded in a medium or in media. In some embodiments, at least two of the one or more operations are executed by a processor of the one or more processors. In some embodiments, at least two of the one or more operations are each executed by a different processor of the one or more processors.

In another aspect, a non-transitory computer program instructions for locating a plurality of stationary components in a facility, the non-transitory computer program instructions, when read by one or more processors, causes the one or more processors to execute operations comprises: (a) initiating, or directing initiation of, at least three of the stationary components at separate locations of the facility; and (b) performing, or directing performance of, a procedure including: (i) activating, or directing activation of, an application configured to receive input, (ii) requesting, or directing request of, input of a location of each of the at least three stationary components, and (iii) storing, or directing storage of, the location for each of the at least three stationary components in a database.

In another aspect, an apparatus for locating a plurality of stationary components in a facility, the apparatus comprises at least one controller configured to execute, or direct execution of, one or more operations of any of the methods disclosed above. In some embodiments, the at least one controller comprises circuitry. In some embodiments, at least two of the one or more operations are executed by a controller of the at least one controller. In some embodiments, at least two of the one or more operations are each executed by a different controllers of the at least one controller.

In another aspect, an apparatus for locating a plurality of stationary components in a facility, the apparatus comprises at least one controller configured to: (a) operatively couple to at least three of the stationary components disposed at separate locations of the facility; (b) initiate, or direct initiation of, the at least three of the stationary components; and (c) perform, or direct performance of, a procedure for each of the at least three stationary components initiated, including: (i) activate, or direct activation of, an application configured to receive input, (ii) request, or direct requesting, input of a location of each of the at least three stationary components, and (iii) store, or direct storage of, the location for each of the at least three stationary components in the database.

In another aspect, a system for locating a plurality of stationary components in a facility, the system comprises at least three stationary components disposed at separate locations of the facility, with each of the at least three stationary components configured to be initiated; and a network operatively coupled to the at least three stationary components and to configured to receive input, which network is configured to facilitate one or more operations of any of the methods disclosed above. In some embodiments, the network is configured to facilitate control at least in part by being configured to transmit control related communication. In some embodiments, the network is configured to facilitate the one or more operations at least in part by being configured to transmit communication of one or more protocols associated with the one or more operations.

In another aspect, a system for locating a plurality of stationary components in a facility, the system comprises: at least three stationary components disposed at separate locations of the facility, with each of the at least three stationary components configured to be initiated; and a network operatively coupled to the at least three stationary components and to an application configured to receive input, which network is configured for communicating with the at least three stationary components to facilitate performing a procedure including: (i) activating the application configured to receive input, (ii) requesting input of a location of each of the at least three stationary components, and (iii) storing the location for each of the at least three stationary components in a database, which network is disposed at least in part in the facility.

In some embodiments, the network is configured for communicating with the at least three stationary components to facilitate performing the procedure at least in part by being configured to transmit communication associated with the procedure. In some embodiments, the application configured to receive the input comprises a user interface. In some embodiments, the user interface comprises a map of at least a portion of the facility. In some embodiments, the map comprises a building information modelling (BIM) file. In some embodiments, the map comprises an architectural plan. In some embodiments, the map comprises a home blueprint file. In some embodiments, the map comprises a three-dimensional home file. In some embodiments, the map comprises a plan view of a room layout of a home. In some embodiments, the facility comprises a home. In some embodiments, the facility comprises a private house. In some embodiments, the private house comprises an apartment in a multi-unit apartment building. In some embodiments, the private house comprises a single family house or a townhouse. In some embodiments, the at least three stationary components configured to be initiated are attached to, or embedded in, one or more fixtures of the facility. In some embodiments, the one or more fixtures comprise a framing. In some embodiments, the one or more fixtures comprise a window framing. In some embodiments, the one or more fixtures comprise a mullion, a transom, a wall, a ceiling, a floor, or any combination thereof. In some embodiments, a stationary component of the plurality of stationary components comprises a sensor, an emitter, a transceiver, or any combination thereof. In some embodiments, a stationary component of the plurality of stationary components comprises a device ensemble. In some embodiments, the device ensemble comprises (i) sensors or (ii) a sensor and an emitter. In some embodiments, a stationary component of the plurality of stationary components comprises a geo-location technology. In some embodiments, the geo-location technology comprises a global positioning system (GPS). In some embodiments, the geo-location technology comprises ultra-wideband. In some embodiments, the geo-location technology comprises a wireless personal area network technology. In some embodiments, the wireless personal area network technology comprises a range of at most about 100 meters, a transmit power of from about 10 Watts to about 100 Watts, a frequency range of from about 2400 Mega Hertz (MHz) to about 2483.5 Mega Hertz, a data rate of from about 0.125 Megabits per second to about 2 Megabits per second (Mb/s), or any combination thereof. In some embodiments, the application is configured to receive the input of the location as a manual input. In some embodiments, the network is configured to facilitate controlling one or more devices of the facility. In some embodiments, the one or more devices comprise a refrigerator, a stove, an oven, a microwave oven, a toaster, an air fryer, a vacuum cleaner system, a washing machine, a clothes dryer, a dish washer, a food processor, a media player, a media screen, a radio, a music player, a heater, a cooler, a ventilator, lighting, a safety related device, a health related device, a tintable window, an automatic door, a heating, ventilation and air conditioning (HVAC) system, or any combination thereof.

In another aspect, a method of locating a transitory component in a facility, the method comprises: (a) transmitting a signal from the transitory component to a plurality of stationary components of the facility, wherein positions of at least three stationary components of the plurality of stationary components have been determined at least in part by considering an external input; and (b) locating the transitory component based at least in part on the positions of the plurality of stationary components.

In some embodiments, the facility comprises a home. In some embodiments, the facility comprises a private house. In some embodiments, the private house comprises an apartment in a multi-unit apartment building. In some embodiments, the private house comprises a single family house or is a townhouse. In some embodiments, for each of the at least three stationary components, the position is defined by a relative position in a map of the facility. In some embodiments, for each of the at least three stationary components, the position is defined by a type of a room of the facility the stationary component is in the facility. In some embodiments, for each of the at least three stationary components, the position is defined by a functionality of a room of the facility the stationary component is in the facility. In some embodiments, the plurality of stationary components is at least three stationary components. In some embodiments, the method further comprises determining positions of other stationary components of the facility that are other than the at least three stationary components, at least in part by determining relative distances of the other stationary components to the at least three stationary components. In some embodiments, determining relative distances of the other stationary components to the at least three stationary components comprises transmitting a signal from the at least three stationary components, which signal is received by the other stationary components, and using the signal to calculate relative positions between the at least three stationary components and the other stationary components. In some embodiments, determining the relative distances of the other stationary components to the at least three stationary components comprises determining the relative distances of the other stationary components relative to each of the at least three stationary components. In some embodiments, determining the positions of the other stationary components comprises determining the positions of the other stationary components relative to each of the at least three stationary components. In some embodiments, the external input comprises a location on a map of at least a portion of the facility for the determining of the positions of the at least three stationary components. In some embodiments, the map comprises a building information modelling (BIM) file. In some embodiments, the map comprises an architectural plan. In some embodiments, the map comprises a home blueprint file. In some embodiments, the map comprises a three-dimensional home file. In some embodiments, the map comprises a plan view of a room layout of a home. In some embodiments, the at least three stationary components are attached to, or embedded in, one or more fixtures of the facility. In some embodiments, the one or more fixtures comprise a framing. In some embodiments, the one or more fixtures comprise a window framing. In some embodiments, the one or more fixtures comprise a mullion, a transom, a wall, a ceiling or a floor. In some embodiments, a stationary component of the plurality of stationary components comprises a sensor, an emitter, a transceiver, or any combination thereof. In some embodiments, a stationary component of the plurality of stationary components is included in a device ensemble. In some embodiments, a stationary component of the plurality of stationary components comprises a geo-location technology. In some embodiments, the geo-location technology comprises a global positioning system (GPS). In some embodiments, the geo-location technology comprises ultra-wideband. In some embodiments, the geo-location technology comprises a wireless personal area network technology. In some embodiments, the wireless personal area network technology comprises a range of at most about 100 meters, a transmit power of from about 10 Watts to about 100 Watts, a frequency range of from about 2400 Mega Hertz (MHz) to about 2483.5 Mega Hertz, a data rate of from about 0.125 Megabits per second to about 2 Megabits per second (Mb/s), or any combination thereof. In some embodiments, the external input is a manual input. In some embodiments, the plurality of stationary components are operatively coupled to a network of the facility, which network is configured to facilitate controlling or more devices of the facility. In some embodiments, the plurality of stationary components are operatively coupled to a control system of the facility, which control system is configured to facilitate controlling one or more devices of the facility. In some embodiments, the control system comprises a building management system (BMS). In some embodiments, the plurality of stationary components are operatively coupled to a network of the facility, which network is configured to facilitate controlling the one or more devices of the facility. In some embodiments, the one or more devices comprise a refrigerator, a stove, an oven, a microwave oven, a toaster, an air fryer, a vacuum cleaner system, a washing machine, a clothes dryer, a dish washer, a food processor, a media player, a media screen, a radio, a music player, a heater, a cooler, a ventilator, lighting, a safety related device, a health related device, a tintable window, an automatic door, a heating, ventilation and air conditioning (HVAC) system, or any combination thereof. In some embodiments, the tintable window comprises an electrochromic window.

In another aspect, a non-transitory computer program instructions for locating a transitory component in a facility, the non-transitory computer program instructions, when read by one or more processors, causes the one or more processors to execute, or direct execution of, one or more operations of any of the methods disclosed above. In some embodiments, the program instructions are embedded in at least one program product. In some embodiments, the program instructions are embedded in a medium or in media. In some embodiments, at least two of the one or more operations are executed by a processor of the one or more processors. In some embodiments, at least two of the one or more operations are each executed by a different processor of the one or more processors.

In another aspect, a non-transitory computer program instructions for locating a transitory component in a facility, the non-transitory computer program instructions, when read by one or more processors, causes the one or more processors to execute operations comprises: (a) transmitting, or directing transmission of, a signal from the transitory component to a plurality of stationary components of the facility, wherein positions of at least three stationary components of the plurality of stationary components have been determined at least in part by considering an external input; and (b) locating, or directing location of, the transitory component based at least in part on the positions of the plurality of stationary components.

In another aspect, an apparatus for locating a transitory component in a facility, the apparatus comprises at least one controller configured to execute, or direct execution of, one or more operations of any of the methods disclosed above. In some embodiments, the at least one controller comprises circuitry. In some embodiments, at least two of the one or more operations are executed by a controller of the at least one controller. In some embodiments, at least two of the one or more operations are each executed by a different controllers of the at least one controller.

In another aspect, an apparatus for locating a transitory component in a facility, the apparatus comprising at least one controller configured to: (a) transmit, or direct transmission of, a signal from the transitory component to a plurality of stationary components of the facility, wherein positions of at least three stationary components of the plurality of stationary components have been determined at least in part by considering an external input; and (b) locate, or directing location of, the transitory component based at least in part on the positions of the plurality of stationary components.

In another aspect, a system for locating a plurality of stationary components in a facility, the system comprises at least three stationary components configured to be located in the facility, each comprises one or more devices configured to (i) communicate between the at least three stationary components and (ii) receive signals from the transitory component, which one or more device comprise a sensor, an emitter, or a transceiver; and a network operatively coupled to the at least three stationary components and to configured to receive input, which network is configured to facilitate one or more operations of any of the methods disclosed above. In some embodiments, the network is configured to facilitate control at least in part by being configured to transmit control related communication. In some embodiments, the network is configured to facilitate the one or more operations at least in part by being configured to transmit communication of one or more protocols associated with the one or more operations.

In another aspect, a system for locating a transitory component in a facility, comprises: a plurality of stationary components of the facility configured to receive a signal transmitted from the transitory component, and a network operatively coupled to the plurality of stationary components, which network is configured to (i) communicate with at least three of the stationary components of the plurality of stationary components, (ii) facilitate determination of positions of the at least three stationary components based at least in part on considering an external input, and (iii) facilitate location of the transitory component based at least in part on the positions of the plurality of stationary components.

In some embodiments, the network is configured to facilitate determination of the positions at least in part by being configured to transmit communication related to the positions, and the network is configured to facilitate location of the transitory component at least in part by being configured to transmit communication related to the location. In some embodiments, the network is configured to facilitate transmission of geo-location signals. In some embodiments, the geo-location signals comprises a global positioning system (GPS). In some embodiments, the geo-location signal comprises ultra-wideband. In some embodiments, the geo-location signal comprises a wireless personal area network technology. In some embodiments, the wireless personal area network technology comprises a range of at most about 100 meters, a transmit power of from about 10 Watts to about 100 Watts, a frequency range of from about 2400 Mega Hertz (MHZ) to about 2483.5 Mega Hertz, a data rate of from about 0.125 Megabits per second to about 2 Megabits per second (Mb/s), or any combination thereof.

In another aspect, a system for locating a transitory component in a facility, the system comprises: at least three stationary components configured to be located in the facility; and a user interface communicatively coupled with the at least three stationary components, which user interface is configured to determine a location of the transitory component based at least in part on the location of the at least three stationary components.

In some embodiments, the user interface is configured to determine the location of the transitory component at least in part by being configured to transmit communication associated with determining the location. In some embodiments, the one or more devices include a source of power. In some embodiments, the one or more devices include a processor, a microcontroller, memory and/or a communication hub. In some embodiments, the communication hub is configured to control data, cellular communication, and/or media communication. In some embodiments, the user interface is configured to communicate to a user the determined location of the transitory component. In some embodiments, each of the at least three stationary components comprises one or more devices configured to receive signals from the transitory component. In some embodiments, the one or more devices comprise (i) sensors, (ii) a sensor and an emitter, (iii) a transceiver, or (iv) any combination thereof. In some embodiments, the one or more devices comprise one or more sensors, one or more emitters, one or more microcontrollers, one or more memories, one or more communication hubs, or any combination thereof. In some embodiments, the one or more communication hubs may be configured to communicate data, control, cellular, media, or any combination thereof. In some embodiments, the user interface is configured to determine the location of the transitory component based at least in part on a signal from the transitory component.

In another aspect, a method of locating a transitory component in a home, the method comprises: (a) transmitting a signal from the transitory component to a plurality of stationary components of the home, which stationary components are operatively coupled to a network configured to facilitate control of at least one device of the home different than the stationary components; and (b) locating the transitory component based at least in part on the positions of the plurality of stationary components.

In some embodiments, the transitory component comprises a cellular phone, an identification tag, a laptop, and/or a pad. In some embodiments, the at least one device includes (i) a service device, (ii) a safety device, (iii) a security device, and/or (iv) a health device. In some embodiments, the service device comprises a refrigerator, a stove an oven, a microwave oven, a toaster an air fryer, a vacuum cleaner system, a washing machine, a dish washer, a clothes dryer, a food processor, a media player, a media screen, a radio, a music player, a heater, a cooler, a ventilator, lighting, a tintable window, an automatic door, or a heating, ventilation and air conditioning (HVAC) system. In some embodiments, the service device is configured to adjust an environment of the home. In some embodiments, the safety device comprises an alarm, an announcement system, alarm lighting, a sensor, a door, a window, or a lock. In some embodiments, the door, window, and/or lock are automatic. In some embodiments, the sensor includes a temperature sensor, a motion sensor, a pressure sensor, an infrared sensor, a visual sensor, and/or an occupancy sensor. In some embodiments, the health device comprises a glucose monitor, a heart rate monitor, a blood pressure monitor, a temperature sensor, an infrared sensor, an ultraviolet sensor or a visual sensor. In some embodiments, the service device includes a processor, or a media display. In some embodiments, the media display comprises a television screen or a computer monitor. In some embodiments, the position of at least three of the plurality of stationary components are determined using an external input. In some embodiments, positions of the plurality of stationary components are determined at least in part by determining relative distances of at least a portion of the plurality of stationary components. In some embodiments, the network comprises a home control system.

In another aspect, a non-transitory computer program instructions for locating a transitory component in a home, the non-transitory computer program instructions, when read by one or more processors, causes the one or more processors to execute, or direct execution of, one or more operations of any of the methods disclosed above. In some embodiments, the program instructions are embedded in at least one program product. In some embodiments, the program instructions are embedded in a medium or in media. In some embodiments, at least two of the one or more operations are executed by a processor of the one or more processors. In some embodiments, at least two of the one or more operations are each executed by a different processor of the one or more processors.

In another aspect, a non-transitory computer program instructions for locating a transitory component in a home, the non-transitory computer program instructions, when read by one or more processors, causes the one or more processors to execute operations comprising: (a) transmitting, or directing transmission of, a signal from the transitory component to a plurality of stationary components of the home, which stationary components are operatively coupled to a network configured to facilitate control of at least one device of the home different than the stationary components; and (b) locating, or directing location of, the transitory component based at least in part on the positions of the plurality of stationary components.

In another aspect, an apparatus for locating a transitory component in a home, the apparatus comprising at least one controller configured to execute, or direct execution of, one or more operations of any of the methods disclosed above. In some embodiments, the at least one controller comprises circuitry. In some embodiments, at least two of the one or more operations are executed by a controller of the at least one controller. In some embodiments, at least two of the one or more operations are each executed by a different controllers of the at least one controller.

In another aspect, an apparatus for locating a transitory component in a home, the apparatus comprises at least one controller configured to: (a) operatively couple to a transitory component, to a plurality of stationary components of the home; (b) direct the transitory component to transmit a signal from the transitory component, which signal is received by the plurality of stationary components of the home, which positions of at least three of the plurality of stationary components have been determined at least in part by considering an external input; (c) locate, or direct location of, the transitory component based at least in part on the positions of the plurality of stationary components; and (d) control at least one device of the home different than the stationary components.

In another aspect, a system for locating a transitory component in a home, the system comprises: a plurality of stationary components of a home, which plurality of stationary components are configured to receive a signal transmitted from the transitory component; and a network operatively coupled to the plurality of stationary components, which network is configured to facilitate (i) control of at least one device of the home different than the stationary components, and (ii) one or more operations of any of the methods disclosed above. In some embodiments, the network is configured to facilitate control at least in part by being configured to transmit control related communication. In some embodiments, the network is configured to facilitate the one or more operations at least in part by being configured to transmit communication of one or more protocols associated with the one or more operations.

In another aspect, a system for locating a transitory component in a home, the system comprises: a plurality of stationary components of a home, which plurality of stationary components are configured to receive a signal transmitted from the transitory component; and a network operatively coupled to the plurality of stationary components, which network is configured to facilitate control of at least one device of the home different than the stationary components, which network is configured to locate the transitory component based at least in part on the positions of the plurality of stationary components. In some embodiments, the network is configured to configured to locate the transitory component at least in part by being configured to transmit communication associated with location of the transitory component.

In another aspect, the present disclosure provides systems, apparatuses (e.g., controllers), and/or non-transitory computer-readable medium (e.g., software) that implement any of the methods disclosed herein.

In another aspect, the present disclosure provides methods that use any of the systems, computer readable media, and/or apparatuses disclosed herein, e.g., for their intended purpose.

In another aspect, an apparatus comprises at least one controller that is programmed to direct a mechanism used to implement (e.g., effectuate) any of the method disclosed herein, which at least one controller is configured to operatively couple to the mechanism. In some embodiments, at least two operations (e.g., of the method) are directed/executed by the same controller. In some embodiments, at less at two operations are directed/executed by different controllers.

In another aspect, an apparatus comprises at least one controller that is configured (e.g., programmed) to implement (e.g., effectuate) any of the methods disclosed herein. The at least one controller may implement any of the methods disclosed herein. In some embodiments, at least two operations (e.g., of the method) are directed/executed by the same controller. In some embodiments, at less at two operations are directed/executed by different controllers.

In another aspect, a system comprises at least one controller that is programmed to direct operation of at least one another apparatus (or component thereof), and the apparatus (or component thereof), wherein the at least one controller is operatively coupled to the apparatus (or to the component thereof). The apparatus (or component thereof) may include any apparatus (or component thereof) disclosed herein. The at least one controller may be configured to direct any apparatus (or component thereof) disclosed herein. The at least one controller may be configured to operatively couple to any apparatus (or component thereof) disclosed herein. In some embodiments, at least two operations (e.g., of the apparatus) are directed by the same controller. In some embodiments, at less at two operations are directed by different controllers.

In another aspect, a computer software product, comprising a non-transitory computer-readable medium in which program instructions are stored, which instructions, when read by at least one processor (e.g., computer), cause the at least one processor to direct a mechanism disclosed herein to implement (e.g., effectuate) any of the method disclosed herein, wherein the at least one processor is configured to operatively couple to the mechanism. The mechanism can comprise any apparatus (or any component thereof) disclosed herein. In some embodiments, at least two operations (e.g., of the apparatus) are directed/executed by the same processor. In some embodiments, at less at two operations are directed/executed by different processors.

In another aspect, the present disclosure provides a non-transitory computer-readable medium comprising machine-executable code that, upon execution by one or more processors, implements any of the methods disclosed herein. In some embodiments, at least two operations (e.g., of the method) are directed/executed by the same processor. In some embodiments, at less at two operations are directed/executed by different processors.

In another aspect, the present disclosure provides a non-transitory computer-readable medium comprising machine-executable code that, upon execution by one or more processors, effectuates directions of the controller(s) (e.g., as disclosed herein). In some embodiments, at least two operations (e.g., of the controller) are directed/executed by the same processor. In some embodiments, at less at two operations are directed/executed by different processors.

In another aspect, the present disclosure provides a computer system comprising one or more computer processors and a non-transitory computer-readable medium coupled thereto. The non-transitory computer-readable medium comprises machine-executable code that, upon execution by the one or more processors, implements any of the methods disclosed herein and/or effectuates directions of the controller(s) disclosed herein.

The content of this summary section is provided as a simplified introduction to the disclosure and is not intended to be used to limit the scope of any invention disclosed herein or the scope of the appended claims.

The disclosure provided herein regarding device(s) can be applicable to respective component(s). The disclosure provided herein regarding firmware can be applicable to software.

Additional aspects and advantages of the present disclosure will become readily apparent to those skilled in this art from the following detailed description, wherein only illustrative embodiments of the present disclosure are shown and described. As will be realized, the present disclosure is capable of other and different embodiments, and its several details are capable of modifications in various obvious respects, all without departing from the disclosure. Accordingly, the drawings and description are to be regarded as illustrative in nature, and not as restrictive.

These and other features and embodiments will be described in more detail with reference to the drawings.

### INCORPORATION BY REFERENCE

All publications, patents, and patent applications mentioned in this specification are herein incorporated by reference to the same extent as if each individual publication, patent, or patent application was specifically and individually indicated to be incorporated by reference.

### BRIEF DESCRIPTION OF THE DRAWINGS

Novel features of the invention are set forth with particularity in the appended claims. A better understanding of the features and advantages of the present invention will be obtained by reference to the following detailed description that sets forth illustrative embodiments, in which the principles of the invention are utilized, and the accompanying drawings or figures (also “FIG.” and “FIGS.” herein), of which:

FIG. 1 schematically depicts a perspective view of an enclosure;

FIG. 2 schematically depicts a network coupled to components in various enclosures;

FIG. 3 schematically depicts component communities;

FIG. 4 schematically depicts a community of components;

FIG. 5 schematically depicts a community of components;

FIG. 6 schematically depicts a community of components;

FIG. 7 schematically depicts a processing system;

FIG. 8 schematically depicts electronic circuitry for a stationary component;

FIG. 9 schematically depicts electronic circuitry for a transitory component;

FIG. 10A schematically depicts components in relation to a time of flight diagram, and FIG. 10B schematically depicts components in relation to a time difference of arrival diagram;

FIG. 11 schematically depicts operations and apparatuses relating to control;

FIG. 12 depicts a flowchart;

FIG. 13 depicts a flowchart; and

FIG. 14 depicts electronic circuitry for a transitory component.

The figures and components therein may not be drawn to scale. Various components of the figures described herein may not be drawn to scale.

### DETAILED DESCRIPTION

While various embodiments of the invention are shown, and described herein, it will be obvious to those skilled in the art that such embodiments are provided by way of example only. Numerous variations, changes, and substitutions may occur to those skilled in the art without departing from the invention. It should be understood that various alternatives to the embodiments of the invention described herein may be employed.

Terms such as “a”, “an” and “the” are not intended to refer to only a singular entity but include the general class of which a specific example may be used for illustration. The terminology herein is used to describe specific embodiments of the invention(s), but their usage does not delimit the invention(s).

When ranges are mentioned, the ranges are meant to be inclusive, unless otherwise specified. For example, a range between value 1 and value 2 is meant to be inclusive and include value 1 and value 2. The inclusive range will span any value from about value 1 to about value 2. The term “adjacent” or “adjacent to,” as used herein, includes ‘next to’, ‘adjoining’, ‘in contact with’, and ‘in proximity to.’

The term “operatively coupled” or “operatively connected” refers to a first mechanism that is coupled (or connected) to a second mechanism to allow the intended operation of the second and/or first mechanism. The coupling may comprise physical or non-physical coupling. The non-physical coupling may comprise signal induced coupling (e.g., wireless coupling).

An element (e.g., mechanism) that is “configured to” perform a function includes a structural feature that causes the element to perform this function. A structural feature may include an electrical feature, such as a circuitry or a circuit element. A structural feature may include an actuator. A structural feature may include a circuitry (e.g., comprising electrical or optical circuitry). Electrical circuitry may comprise one or more wires. Optical circuitry may comprise at least one optical element (e.g., beam splitter, mirror, lens and/or optical fiber). A structural feature may include a mechanical feature. A mechanical feature may comprise a latch, a spring, a closure, a hinge, a chassis, a support, a fastener, or a cantilever, and so forth. Performing the function may comprise utilizing a logical feature. A logical feature may include programming instructions. Programming instructions may be executable by at least one processor. Programming instructions may be stored or encoded on a medium accessible by one or more processors. Additionally, in the following description, the phrases “operable to,” “adapted to,” “configured to,” “designed to,” “programmed to,” or “capable of” may be used interchangeably where appropriate.

As used herein, including the claims, the conjunction “and/or” in a phrase such as “including X, Y, and/or Z”, refers to in inclusion of any combination or plurality of X, Y, and Z. For example, such phrase is meant to include X. For example, such phrase is meant to include Y. For example, such phrase is meant to include Z. For example, such phrase is meant to include X and Y. For example, such phrase is meant to include X and Z. For example, such phrase is meant to include Y and Z. For example, such phrase is meant to include a plurality of Xs. For example, such phrase is meant to include a plurality of Ys. For example, such phrase is meant to include a plurality of Zs. For example, such phrase is meant to include a plurality of Xs and a plurality of Ys. For example, such phrase is meant to include a plurality of Xs and a plurality of Zs. For example, such phrase is meant to include a plurality of Ys and a plurality of Zs. For example, such phrase is meant to include a plurality of Xs and Y. For example, such phrase is meant to include a plurality of Xs and Z. For example, such phrase is meant to include a plurality of Ys and Z. For example, such phrase is meant to include X and a plurality of Ys. For example, such phrase is meant to include X and a plurality of Zs. For example, such phrase is meant to include Y and a plurality of Zs. The conjunction “and/or” is meant to have the same effect as the phrase “X, Y, Z, or any combination or plurality thereof.” The conjunction “and/or” is meant to have the same effect as the phrase “one or more X, Y, Z, or any combination thereof.” The conjunction “and/or” is meant to have the same effect as the phrase “at least one X, Y, Z, or any combination thereof.”

In some embodiments, an enclosure comprises an area defined by at least one structure. The at least one structure may comprise at least one wall. An enclosure may comprise and/or enclose one or more sub-enclosure. The at least one wall may comprise metal (e.g., steel), clay, stone, plastic, glass, plaster (e.g., gypsum), polymer (e.g., polyurethane, styrene, or vinyl), asbestos, fiber-glass, concrete (e.g., reinforced concrete), wood, paper, or a ceramic. The at least one wall may comprise wire, bricks, blocks (e.g., cinder blocks), tile, drywall, or frame (e.g., steel frame).

In some embodiments, the enclosure comprises one or more openings. The one or more openings may be reversibly closable. The one or more openings may be permanently open. A fundamental length scale of the one or more openings may be smaller relative to the fundamental length scale of the wall(s) that define the enclosure. A fundamental length scale may comprise a diameter of a bounding circle, a length, a width, or a height. A surface of the one or more openings may be smaller relative to the surface the wall(s) that define the enclosure. The opening surface may be a percentage of the total surface of the wall(s). For example, the opening surface can measure about 30%, 20%, 10%, 5%, or 1% of the walls(s). The wall(s) may comprise a floor, a ceiling or a side wall. The closable opening may be closed by at least one window or door. The enclosure may be at least a portion of a facility. The enclosure may comprise at least a portion of a building. The building may be a private building and/or a commercial building. The building may comprise one or more floors. The building (e.g., floor thereof) may include at least one of: a room, hall, foyer, attic, basement, balcony (e.g., inner or outer balcony), stairwell, corridor, elevator shaft, façade, mezzanine, penthouse, garage, porch (e.g., enclosed porch), terrace (e.g., enclosed terrace), cafeteria, and/or Duct. The facility may comprise a home, a private house, an apartment in a multi-unit apartment building, a single family house, a townhouse, and/or any habitable building. An indicator of a layout of at least a portion of the facility may be available. The indicator of a layout may include a map, a building information modelling (BIM) file, an architectural plan, a blueprint file, a three-dimensional building (e.g., home) file and/or a plan view of a room layout of a building.

In some embodiments, the enclosure encloses an atmosphere. The atmosphere may comprise one or more gases. The gases may include inert gases (e.g., argon or nitrogen) and/or non-inert gases (e.g., oxygen or carbon dioxide). The enclosure atmosphere may resemble an atmosphere external to the enclosure (e.g., ambient atmosphere) in at least one external atmosphere characteristic that includes: temperature, relative gas content, gas type (e.g., humidity, and/or oxygen level), debris (e.g., dust and/or pollen), and/or gas velocity. The enclosure atmosphere may be different from the atmosphere external to the enclosure in at least one external atmosphere characteristic that includes: temperature, relative gas content, gas type (e.g., humidity, and/or oxygen level), debris (e.g., dust and/or pollen), and/or gas velocity. For example, the enclosure atmosphere may be less humid (e.g., drier) than the external (e.g., ambient) atmosphere. For example, the enclosure atmosphere may contain the same (e.g., or a substantially similar) oxygen-to-nitrogen ratio as the atmosphere external to the enclosure. The velocity of the gas in the enclosure may be (e.g., substantially) similar throughout the enclosure. The velocity of the gas in the enclosure may be different in different portions of the enclosure (e.g., by flowing gas through to a vent that is coupled with the enclosure).

Certain disclosed embodiments provide a network infrastructure in the enclosure (e.g., a facility such as a building). The network infrastructure is available for various purposes such as for providing communication and/or power services. The communication services may comprise high bandwidth (e.g., wireless and/or wired) communications services. The communication services can be to occupants of a facility and/or users outside the facility (e.g., building). The network infrastructure may work in concert with, or as a partial replacement of, the infrastructure of one or more cellular carriers. The network infrastructure can be provided in a facility that includes electrically switchable windows. Examples of components of the network infrastructure include a high speed backhaul. The network infrastructure may include at least one cable, switch, physical antenna, transceivers, sensor, transmitter, receiver, radio, processor and/or controller (that may comprise a processor). The network infrastructure may be operatively coupled to, and/or include, a wireless network. The network infrastructure may comprise wiring. One or more sensors can be deployed (e.g., installed) in an environment as part of installing the network and/or after installing the network. One or more transceivers can be deployed (e.g., installed) in an environment as part of installing the network and/or after installing the network.

In various embodiments, a network infrastructure supports a control system for one or more windows such as tintable (e.g., electrochromic) windows. The control system may comprise one or more controllers operatively coupled (e.g., directly or indirectly) to one or more windows. While the disclosed embodiments describe tintable windows (also referred to herein as “optically switchable windows,” or “smart windows”) such as electrochromic windows, the concepts disclosed herein may apply to other types of switchable optical devices comprising a liquid crystal device, an electrochromic device, suspended particle device (SPD), NanoChromics display (NCD), Organic electroluminescent display (OELD), suspended particle device (SPD), NanoChromics display (NCD), or an Organic electroluminescent display (OELD). The display element may be attached to a part of a transparent body (such as the windows).

In some embodiments, one or more components may be disposed in or on a fixed in space enclosure. In some embodiments, one or more components may be mobile. An enclosure may comprise a portion of a building (e.g., having a geographical location, e.g., having a municipal address). A building may be a residential building and/or a commercial building. An enclosure may comprise and/or enclose one or more sub-enclosures. An enclosure may include a room, a lobby, hall, a duct, a foyer, an attic, a basement, a balcony (e.g., inner or outer balcony), a stairwell, a corridor, an elevator shaft, a mezzanine, a penthouse, a garage, a porch (e.g., enclosed porch), a terrace (e.g., enclosed terrace), and/or a cafeteria. An enclosure may include a floor and/or a level. An enclosure may include one or more elements. An element may comprise interior facing wall, exterior facing wall, ceiling, floor, window, entrance, door, opening, beam, stair, facade, molding, mullion, or transom.

In some embodiments, an enclosure comprises one or more sensors (e.g., as part of one or more transceivers, e.g., respectively). An enclosure can comprise at least one wall that defines the enclosure. The at least one wall may comprise metal (e.g., steel), clay, stone, plastic, glass, plaster (e.g., gypsum), polymer (e.g., polyurethane, styrene, or vinyl), asbestos, fiber-glass, concrete (e.g., reinforced concrete), wood, paper, or a ceramic. The at least one wall may comprise wire, bricks, blocks (e.g., cinder blocks), tile, drywall, or frame (e.g., steel frame).

In some embodiments, the enclosure comprises one or more openings. The one or more openings may be reversibly closable. The one or more openings may be permanently open. A fundamental length scale (FLS) of the one or more openings may be smaller relative to the fundamental length scale of the wall(s) that define the enclosure. A fundamental length scale may comprise a diameter of a bounding circle, a length, a width, or a height. A surface of the one or more openings may be smaller relative to the surface the wall(s) that define the enclosure. The opening surface may be a percentage of the total surface of the wall(s). For example, the opening surface can measure about 30%, 20%, 10%, 5%, or 1% of the walls(s). The wall(s) may comprise a floor, a ceiling or a side wall. The closable opening may be closed by at least one window or door. The enclosure may be at least a portion of a facility. The enclosure may comprise at least a portion of a building. The building may be a private building and/or a commercial building. The building may comprise one or more floors. The building (e.g., floor thereof) may include at least one of: a room, hall, foyer, attic, basement, balcony (e.g., inner or outer balcony), stairwell, corridor, elevator shaft, façade, mezzanine, penthouse, garage, porch (e.g., enclosed porch), terrace (e.g., enclosed terrace), cafeteria, and/or Duct.

In some embodiments, the enclosure encloses an atmosphere. The atmosphere may comprise one or more gases. The gases may include inert gases (e.g., argon or nitrogen) and/or non-inert gases (e.g., oxygen or carbon dioxide). The enclosure atmosphere may resemble an atmosphere external to the enclosure (e.g., ambient atmosphere) in at least one external atmosphere characteristic that includes: temperature, relative gas content, gas type (e.g., humidity, and/or oxygen level), debris (e.g., dust and/or pollen), and/or gas velocity. The enclosure atmosphere may be different from the atmosphere external to the enclosure in at least one external atmosphere characteristic that includes: temperature, relative gas content, gas type (e.g., humidity, and/or oxygen level), debris (e.g., dust and/or pollen), and/or gas velocity. For example, the enclosure atmosphere may be less humid (e.g., drier) than the external (e.g., ambient) atmosphere. For example, the enclosure atmosphere may contain the same (e.g., or a substantially similar) oxygen-to-nitrogen ratio as the atmosphere external to the enclosure. The velocity of the gas in the enclosure may be (e.g., substantially) similar throughout the enclosure. The velocity of the gas in the enclosure may be different in different portions of the enclosure (e.g., by flowing gas through to a vent that is coupled with the enclosure).

Some embodiments provide a network infrastructure in the enclosure (e.g., a facility such as a building). The network infrastructure is available for various purposes such as for providing communication and/or power services. The communication services may comprise high bandwidth (e.g., wireless and/or wired) communications services. The communication services can be to occupants of a facility and/or users outside the facility (e.g., building). The network infrastructure may work in concert with, or as a partial replacement of, the infrastructure of one or more cellular carriers. The network infrastructure can be provided in a facility that includes electrically switchable windows. Examples of components of the network infrastructure include a high speed backhaul. The network infrastructure may include at least one cable, switch, physical antenna, transceivers, sensor, transmitter, receiver, radio, processor and/or controller (that may comprise a processor). The network infrastructure may be operatively coupled to, and/or include, a wireless network. The network infrastructure may comprise wiring.

In some embodiments, the community of components includes specialized and/or non-specialized components. The components may include sensors, actuators, transmitters, receivers, transceivers, processors, and/or controllers. The non-specialized components may be stationary or mobile. Components may be configured to process, measure, analyze, detect and/or react to one or more of: data, temperature, humidity, sound, force, electromagnetic waves, position, distance, movement, acceleration, speed, vibration, volatile compounds (e.g., Volatile Organic Compounds abbreviated herein as “VOCs”), dust, light, glare, color, gas(es), and/or other aspects (e.g., characteristics) of the enclosure. Gases may be one or more of: carbon monoxide, carbon dioxide, water vapor (e.g., humidity), oxygen, radon, and hydrogen sulfide. The gas(es) may be present in an ambient environment. The gas(es) may comprise an inert gas. The VOCs and/or gasses may include compound(s) such as Nitric oxide (NO), nitrogen dioxide (NO₂), and/or formaldehyde).

One or more component may be coupled to (e.g., installed on, or in) an enclosure. For example, the one or more components may be coupled to elements of the enclosure. The element of the enclosure may include a wall, a door, a window, a door frame, a window frame, and/or a duct (e.g., air duct and/or an electrical duct). A component may be included in the element of the enclosure. A component may be coupled to an element directly or indirectly. Coupled to may include fastened to, glued to, contacted with, electronically connected to, wired to, and/or tied to. A component may be easy to remove from an element (e.g., removable), or it may be permanently coupled to the element (e.g., hard to remove from an element without causing damage to the element). Easy to remove may include reversibly removable. For example, the component may be attached and detached to the element reversibly, e.g., with no aesthetic and/or detectable damage to the element and/or to the component. A component may be configured to attach (e.g., reversibly) to one or more element of an enclosure. The component may be reversibly or irreversibly attached to the element of the enclosure. A component may be configured to fit into and/or snap onto an element (e.g., fit into and/or attached on to a mullion). At least two components may be coupled to the same circuit board. At least two components may be coupled to separate circuit boards. A component ensemble may comprise two or more components (e.g., one or more sensor and one or more processor). In some embodiments, a component ensemble is coupled (e.g., disposed in) to a single circuit board. Two or more components may be part of a larger system (e.g., a module). Examples of components and modules are provided in U.S. patent application Ser. No. 16/447,169, titled “SENSING AND COMMUNICATIONS UNIT FOR OPTICALLY SWITCHABLE WINDOW SYSTEMS,” filed Jun. 20, 2019, which is incorporated herein by reference in its entirety. A component may communicate with, or be operatively (e.g., functionally) coupled, to other components wirelessly or via one or more wires (e.g., one or more wireless camera may communicate with one or more processor via radio waves).

In some embodiments, a tintable window exhibits a (e.g., controllable and/or reversible) change in at least one optical property of the window, e.g., when a stimulus is applied. The optical property may comprise hue, or transmissivity. The hue may comprise color. The transmissivity may be of one or more wavelengths. The wavelengths may comprise ultraviolet, visible, or infrared wavelengths. The stimulus can include an optical, electrical and/or magnetic stimulus. For example, the stimulus can include an applied voltage and/or current. One or more tintable windows can be used to control lighting and/or glare conditions, e.g., by regulating the transmission of solar energy propagating through them. One or more tintable windows can be used to control a temperature within a building, e.g., by regulating the transmission of solar energy propagating through the window. Control of the solar energy may control heat load imposed on the interior of the facility (e.g., building). The control may be manual and/or automatic. The control may be used for maintaining one or more requested (e.g., environmental) conditions, e.g., occupant comfort. The control may include reducing energy consumption of a heating, ventilation, air conditioning and/or lighting systems. At least two of heating, ventilation, and air conditioning may be induced by separate systems. At least two of heating, ventilation, and air conditioning may be induced by one system. The heating, ventilation, and air conditioning may be induced by a single system (abbreviated herein as “HVAC). In some cases, tintable windows may be responsive to (e.g., and communicatively coupled to) one or more environmental sensors and/or user control. Tintable windows may comprise (e.g., may be) electrochromic windows. The windows may be located in the range from the interior to the exterior of a structure (e.g., facility, e.g., building). However, this need not be the case. Tintable windows may operate using liquid crystal devices, suspended particle devices, microelectromechanical systems (MEMS) devices (such as microshutters), or any technology known now, or later developed, that is configured to control light transmission through a window. Windows (e.g., with MEMS devices for tinting) are described in U.S. Pat. No. 10,359,681 B2, issued Jul. 23, 2019, filed May 15, 2015, titled “MULTI-PANE WINDOWS INCLUDING ELECTROCHROMIC DEVICES AND ELECTROMECHANICAL SYSTEMS DEVICES,” and incorporated herein by reference in its entirety. In some cases, one or more tintable windows can be located within the interior of a building, e.g., between a conference room and a hallway.

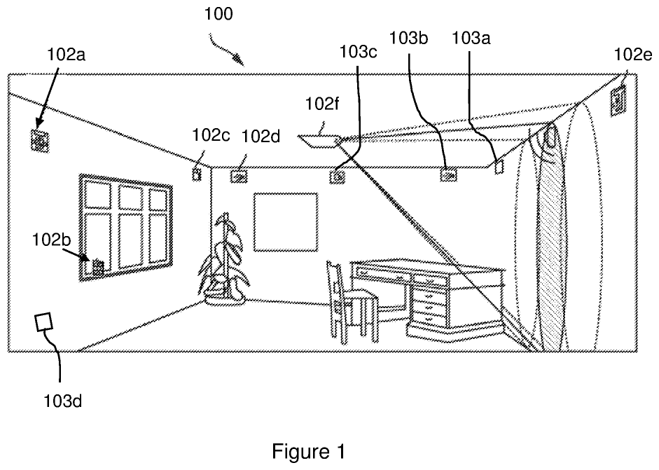

FIG. 1 shows an example of a community of components coupled to elements of an enclosure. In the example shown in FIG. 1, a community of components 102a-102e is coupled to elements of an enclosure 100 comprised of interior facing walls, a ceiling and a window. Component 102a can represent one or more gas sensor configured to measure, analyze, and/or provide indications of ambient CO₂ levels within an enclosure. Component 102b can represent one or more controller configured to control functions of one or more window. A window may comprise an optically switchable window, e.g., an electrochromic window. Examples of optically switchable windows, controllers, and methods of use of are provided in U.S. patent application Ser. No. 16/462,916, filed May 21, 2019, titled “AUTOMATED COMMISSIONING OF CONTROLLERS IN A WINDOW NETWORK,” which is incorporated herein by reference in its entirety. Component 102c can represent one or more sound sensor configured to measure, analyze, and/or provide indications of sound levels, present within the enclosure. Component 102d can represent one or more light sensor configured to measure, analyze, and/or provide indications of light and/or glare present within the enclosure. Component 102e can represent one or more transceiver configured to receive and transmit radio waves within the enclosure. Component 102f can represent one or more processor configured to process signals transmitted by one or more of components 102a-102e. Some community of components may have at least two components of the same type (e.g., two temperature sensors). For example, all members of the community of components may be of the same type. Some community of components may have at least two components of different type (e.g., a temperature sensor and a pressure sensor). For example, all members of the community of components may be of different types. In some embodiments, a single component may provide the functionality of two or more components (e.g., a force sensor that is used to detect vibration and movement). In some embodiments, components with functionalities other than disclosed herein may be used. In some embodiments, components may be provided on, or in, elements other than disclosed herein.

In some embodiments, the community of components facilitates control of one or more (e.g., different types of) devices of a facility. The one or more devices may include a refrigerator, a stove, an oven, a microwave oven, a toaster, an air fryer, a vacuum cleaner system, a washing machine, a clothes dryer, a dish washer, a food processor, a media player, a media screen, a radio, a music player, a heater, a cooler, a ventilator, lighting, a safety related device, a health related device, a tintable window, an automatic door, a heater, a cooler, a vent, and/or a heating, ventilation and air conditioning (HVAC) system. The community of components may be controlled. The community of components may be utilized for control of one or more devices. or control may be facilitated via a network. The network may be operatively coupled to a control system of the facility (e.g., of the home). A control system may comprise a building management system (BMS), or may be operatively coupled to a BMS.

In the example shown in FIG. 1, a plurality of stationary components 103a-103d may be coupled to the facility, and may communicate via wires and/or wirelessly with a network. A network may comprise a wired and/or wireless router (e.g., a home router). Wireless communication may comprise cellular communication, e.g., abiding by at least a third, fourth, or fifth generation communication protocol. Stationary components may be attached to and/or embedded in one or more fixtures of the facility. The one or more fixtures may comprise framing, window framing, a transom, a wall, a ceiling, a roof, and/or a floor. Stationary components may plugged into an electrical outlet, a powered Ethernet of a local (e.g., residential) network, a coaxial cable (e.g., that facilitates transmission of power and communication on the same cable), or any other source of electric power (e.g., renewable electrical power such as a solar cell). While an example shown in FIG. 1 shows four stationary components, three or more than three stationary components may be employed within a facility. One or more stationary components of the plurality of stationary components may be disposed in different rooms of the facility. One or more of the stationary components may be included in a device ensemble. A device ensemble may comprise one or more sensors, one or more emitters, one or more transceivers, and/or other combinations these electronic components. The device ensemble may comprise one or more processors, and/or processor components (e.g., as disclosed herein).

In the example shown in FIG. 1, the location of at least a portion of the plurality of stationary components 103a-103d can be determined. One or more of the stationary components may comprise geo-location technology. Geo-location technology may comprise a Global Positioning System (GPS), ultra-wideband and/or a wireless personal area network technology. Wireless personal area network technology (e.g., Bluetooth) may comprise a range of about 100 meters, a transmit power of from about 10 Watts to about 100 Watts, a frequency range of from about 2400 Mega Hertz to about 2483.5 Mega Hertz, a data rate of from about 0.125 Megabits per second to about 2 Megabits per second, or any combination thereof.

In some embodiments, a plurality of components (e.g., devices) may be operatively (e.g., communicatively) coupled to the control system. The plurality of components may be disposed in a facility (e.g., including a building and/or room). The control system may comprise the hierarchy of controllers. The components may comprise an emitter, a sensor, a transceiver, or a window (e.g., IGU). The component may be any component as disclosed herein. At least two of the plurality of components may be of the same type. For example, two or more IGUs may be coupled to the control system. At least two of the plurality of components may be of different types. For example, a sensor and an emitter may be coupled to the control system. At times the plurality of components may comprise at least 20, 50, 100, 500, 1000, 2500, 5000, 7500, 10000, 50000, 100000, or 500000 components. The plurality of components may be of any number between the aforementioned numbers (e.g., from 20 components to 500000 components, from 20 components to 50 components, from 50 components to 500 components, from 500 components to 2500 components, from 1000 components to 5000 components, from 5000 components to 10000 components, from 10000 components to 100000 components, or from 100000 components to 500000 components). For example, the number of windows in a floor may be at least 5, 10, 15, 20, 25, 30, 40, or 50. The number of windows in a floor can be any number between the aforementioned numbers (e.g., from 5 to 50, from 5 to 25, or from 25 to 50). At times the components may be in a multi-story building. At least a portion of the floors of the multi-story building may have components controlled by the control system (e.g., at least a portion of the floors of the multi-story building may be controlled by the control system). For example, the multi-story building may have at least 2, 8, 10, 25, 50, 80, 100, 120, 140, or 160 floors that are controlled by the control system. The number of floors (e.g., components therein) controlled by the control system may be any number between the aforementioned numbers (e.g., from 2 to 50, from 25 to 100, or from 80 to 160). The floor may be of an area of at least about 150 m², 250 m², 500 m², 1000 m², 1500 m², or 2000 square meters (m²). The floor may have an area between any of the aforementioned floor area values (e.g., from about 150 m² to about 2000 m², from about 150 m² to about 500 m². from about 250 m² to about 1000 m², or from about 1000 m² to about 2000 m²). The facility may be a residential building (e.g., a single family house).

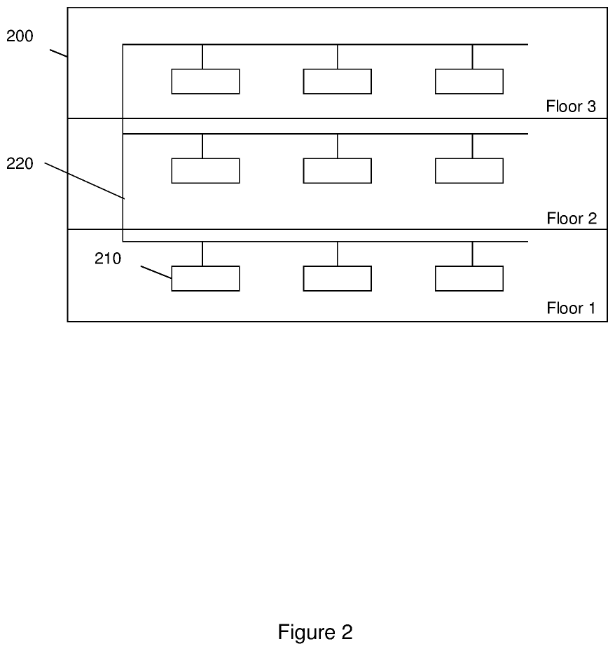

FIG. 2 shows a schematic example of a network within an enclosure. In the example of FIG. 2, the enclosure 200 is a building having floor 1, floor 2, and floor 3. The enclosure 200 includes a network 220 (e.g., wired network) that is provided to communicatively couple a community of components 210. In the example shown in FIG. 2, the three floors are sub enclosures within the enclosure 200.

Communication within a community of components that are coupled to a network may be coordinated by at least one component. The component may be part of the community. The component may comprise a controller. A controller may be located within an enclosure that houses the components being controlled by the controller, or the controller may be disposed outside of the enclosure that houses the components. For example, the controller may be located remotely relative to the enclosure housing the controller. The remote location may be physical or virtual (e.g., in the cloud). A controller may communicate with a community of components wirelessly of via one or more wires. A controller may include, but is not limited to, a processor, a local or distributed server, a building management system, a sensor management system, an environmental management system, a component controller, and/or a window controller. Examples of window controllers, and methods of use of are provided in U.S. patent application Ser. No. 16/096,557, titled “CONTROLLING OPTICALLY-SWITCHABLE DEVICES,” filed Oct. 25, 2018, which is incorporated herein by reference in its entirety. In some embodiments, the component comprises a controller. In some embodiments, the component may function as a controller. The controller may be temporarily assigned to the community of components. The controller may be permanently assigned to the community of the components (e.g., during the operative life of the community and of the controller).

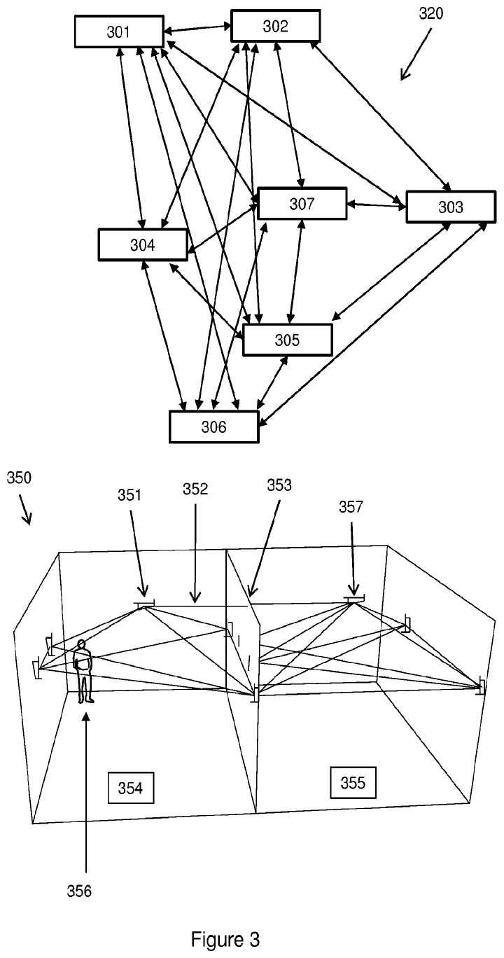

FIG. 3 shows an example of a topology of a community of components connected by a network. FIG. 3 shown an example of components 301-307 that are communicative coupled to form a communication network of components 320. The community of components can be configured to communicate via a network, and/or form a communication network. The arrows of the network shown in the example of FIG. 3, depict a possible (e.g., allowed) direction of communication (e.g., a direction of signal propagation). A network may be a wired and/or a wireless network. One or more component of a community of components may be powered by an onboard power source and/or powered by a remote power source. Power to one or more component of a community of components may be provided wirelessly (e.g., harvested energy) and/or via wires. The power may be from a renewable energy source (e.g., from a solar panel). The power may be from a non-renewable energy source (e.g., from a power plant using non-renewable energy).

FIG. 3 shows in 350 an example of a community of network disposed in an enclosure comprising two sub enclosures 354 and 355 (e.g., two rooms). Component 351 is part of the community of components disposed in a first sub-enclosure 354 (e.g., room) in which a person 356 is in, and component 357 is part of the community of components disposed in a second sub-enclosure 355 (e.g., room) that is not occupied by any person. A wall 353 separates the two sub-enclosures in the example shown in FIG. 3, that also shows possible (e.g., allowed) communication routes between the components, schematically depicted as lines (e.g., 352). At times, the community of components may span more than one enclosure or sub-enclosures. For example, at least part of (e.g., all of) the components from the two sub-enclosures 354 and 355 constitute one community of components. At times, the community of components may span one enclosure or sub-enclosures. For example, at least part of (e.g., all of) the components from sub-enclosure 354 constitute one community of components, that excludes the components in enclosure 355. The physical fundamental length scale of the community of components may depend on the range of signal transmission.

In some embodiments, a topology of a community of components is determined. The topology may be determined, at least in part, by a moving or stationary person and/or a machine. A traveler may be a moving person or machine. The topology may be absolutely determined or relatively determined. The absolute coordination may be determined based at least in part on global positioning system (GPS) coordinates. A relative determination of coordinates may include relative position of the components in relation to one another. A topology of a community of components may be determined from distances and/or angles measured between the community of components. A topology of a community of components may be determined by one or more processor configured to perform (or direct performance of) (I) measurements and/or analysis of: (I) time of flight of one or more signals propagating between the components (e.g., signal between component 302 and 307 of FIG. 3), (II) response times of components, (III) distances and/or angles between components. The one or more processors may be of a component or of two or more components. Measurements and/or analysis may be stored as data in one or more memory associated with, or operatively coupled to, one or more processor. The memory may be disposed in the enclosure, or outside of the enclosure. The memory may be disposed in the cloud, or in another facility (e.g., in another building). Measurements between a community of components may define constraints. The constraints may be utilized by at least one processor to determine a relative distance between the community members. The processor may utilize data stored in at least one memory. The processor may utilize one or more calculations (e.g., triangulation) to determine the relative position of the components. In one embodiment, once distances between at least three (3) components disposed in a common plane are determined, the positions of the other components of the community may be determined relative to the three components. Each of the three components may have associated Cartesian coordinates (e.g., X, Y, and Z). The three components may have at least two of their Cartesian coordinates different from each other (e.g., the three components are different in at least two dimensions). For example, the three components may have all three of their Cartesian coordinates different (e.g., the three components are different in three dimensions). As the number of components is increased, a topology's (e.g., relative) positional accuracy may improve. The topology may be displayed (e.g., on a user interface communicatively coupled to the community of components). In one embodiment, a location and/or relative position of three or more components may be input relative to a map and/or database of at least a portion of the facility. The map may be a digital map. The map may comprise a building information modelling (BIM) file, an architectural plan, a building blueprint file, a three-dimensional building file, and/or a plan view of a layout of a building. The facility may comprise a home.

In some embodiments, one or more component of a community of components comprises a transceiver. In some embodiments, a transceiver may be configured transmit and receive one or more signals using a personal area network (PAN) standard, for example such as IEEE 802.15.4. In some embodiments, signals may comprise Bluetooth, Wi-Fi, or EnOcean signals (e.g., wide bandwidth). The one or more signals may comprise ultra-wide bandwidth (UWB) signals (e.g., having a frequency in the range from about 2.4 to about 10.6 Giga Hertz (GHz), or from about 7.5 GHz to about 10.6 GHZ). An Ultra-wideband signal can be one having a fractional bandwidth greater than about 20%. An ultra-wideband signal can have a bandwidth greater than about 500 Mega Hertz (MHz). The one or more signals may use a very low energy level for short-range. Signals (e.g., having radio frequency) may employ a spectrum capable of penetrating solid structures (e.g., wall, door, and/or window). Low power may be of at most 25 milli Watts (mW), 50 mW, 75 mW, or 100 mW. Low power may be any value between the aforementioned values (e.g., from 25 mW to 100 mW, from 25 mW to 50 mW, or from 75 mW to 100 mW).

Signals may be transmitted at predetermined times and/or intervals. The predetermined time may be fixed or changing. The time may be predetermined, e.g., by a controller. FIG. 3 shows an example of signal transmission between components. In the example of FIG. 3, signals are sent over network 320 by a transmitter of a component 301 and are received by receivers of components 302-307. In the example of FIG. 3, signals are sent by transmitters of components 302-307 and are received by a receiver of component 301. In the example of FIG. 3, signals are sent over network 320 by transmitter and receivers of the other components 302-307. Time of flight of signals between transmitters of components and receivers of components may be (i) stored as distance data in at least one memory and/or (ii) may be retrieved to determine a relative distance between the components. The relative distance may be utilized to create a map or topology of the community of components. The retrieval from memory may utilize data processing, e.g., by at least one processor. Other data types may include, but are not limited to: angle data, position data, location data, control data, sensor data, and/or component identification information data. The data may be stored in at least one memory. The data may be communicated over the network.

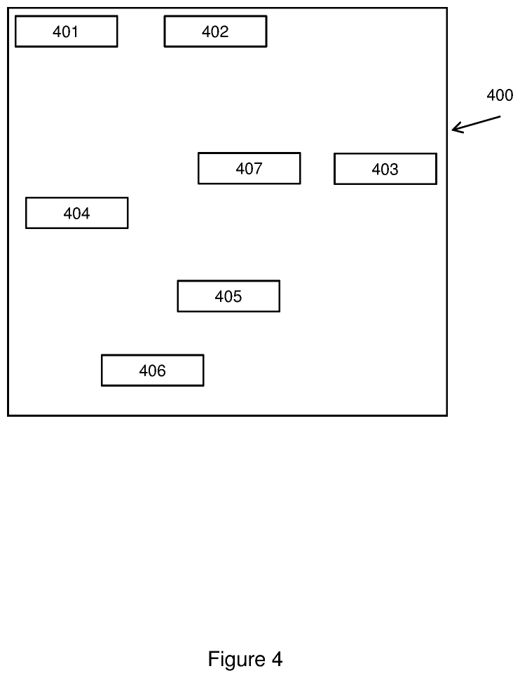

FIG. 4 shows an example of a topology of the community of components (e.g., such as the one represented in FIG. 3) in an enclosure. A community of components may be disposed in one or more enclosures during initial construction of the enclosure or after construction of the enclosure. After placement in an enclosure, one or more signals sent between the components may be analyzed and/or used to determine a topology of the community of components. Determination of a topology of a community of components by itself may not determine an absolute position of the components in a topology of an enclosure. A lack of knowledge of the position of the component, may make its data interpretation, data usage, calibration, replacement, maintenance, and/or repair difficult. For example, it may hinder forming an accurate distribution mapping of a sensed environmental characteristic (e.g., heat, pressure, or humidity) in the enclosure. For example, is may skew determination of a position of the sensed environmental characteristic. For example, it may direct maintenance personnel to a wrong location within the enclosure.

A topology of components in an enclosure may be determined (and/or displayed) using data embodied in the form of determined distances and/or angles between elements of the enclosure (e.g., distances and/or angles between wall, floors, and/or ceilings). A topology may comprise a two dimensional topology and/or a three dimensional topology. In the example shown in FIG. 4, a topology of an enclosure 400 and a community of components 401-407 comprises a two dimensional d topology. A topology of an enclosure and/or a topology of a community of components may be embodied in the form of a physical and/or virtual representation of the topology (e.g., a blueprint, architectural drawing, floorplan, and/or three dimensional software representation). A topology of a community of components and/or a topology of an enclosure may be stored as data in at least one memory associated with one or more processors that are in turn associated with one or more components. A topology may comprise a printed or printable topology, a displayed or displayable topology, and/or a topology comprised of data read or readable by a processor.

In some embodiments, at least one component of a community of components is (e.g., designated as) a reference component (e.g., at least one of components 401-407 in the example of FIG. 4). The reference component may be associated and/or assigned to a known location within an enclosure. The one or more reference components in the enclosure may be at most 1, 2, 3, 4, 5, or 10 components. The one or more reference components in the enclosure may be any number between the aforementioned numbers (e.g., from 1 to 10, from 1 to 5, or from 5 to 10 components). A reference component may be associated with a location within an enclosure before or after placement of a community of components within an enclosure. In one embodiment, assignment of a reference component may be performed via software (e.g., using the network and/or a controller). Assignment of a reference component may include virtual placement onto a location of a software generated representation of an enclosure. Assignment of a reference component may include its physical placement in an enclosure and/or its virtual placement onto a location of a software generated representation of an enclosure. A software generated representation of an enclosure may comprise a two dimensional and/or a three dimensional representation. A software generated representation of an enclosure may be digitally represented, and/or displayed, e.g., on an electronic display. A user may interact with the digital representation. For example, a user may interact with an electronic display via a graphical user interface (abbreviated herein as “GUI”) that may be configured to enable assignment (and/or reassignment) of one or more reference components via user interaction (e.g., via data entry, dragging and/or dropping).

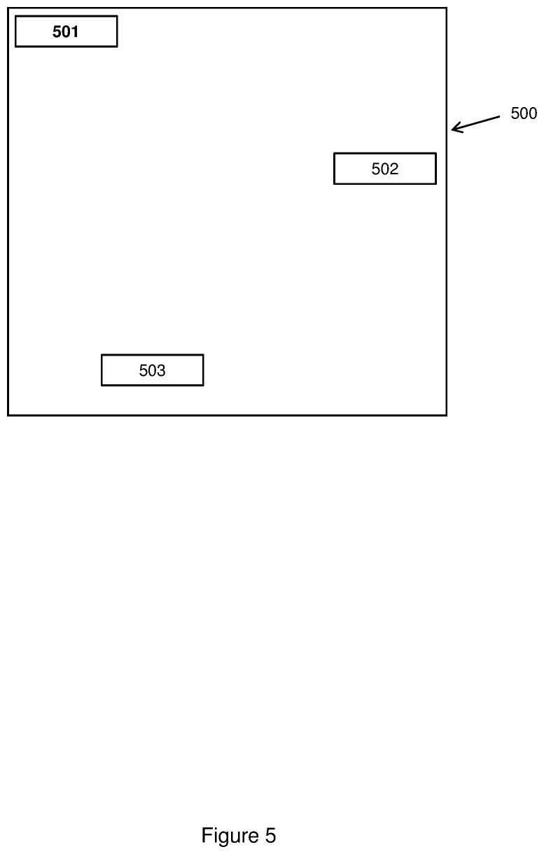

FIG. 5 shows an example of an orientation of a topology of a community of components comprised of three reference components. In FIG. 5, a community of components 501-503 is physically placed within an enclosure 500, wherein 501-503 are reference components. A topology of the components in an enclosure may be printed and/or displayed as a blueprint, architectural drawing and/or floorplan of the enclosure to find locations of components within the enclosure. If one or more components move, are moved, added to, or removed from a community of components, a new topology of the components may be determined. The topology may be of the components relative to each other and/or relative to the enclosure. When an absolute topology (e.g., in relation to absolute coordinates, e.g., GPS) is requested, then the absolute coordinates of at least one of the components is required. In order to determine an absolute location of a components in three dimensions, then three components having all three Cartesian coordinates different from each other may be required (e.g., using a triangulation mapping method). A calibrated and/or localized component may be utilized as a standard for calibrating and/or localizing other components.

In some embodiments, locations of all components of the community are determined. In order to form a two dimensional topological mapping in an environment, a component is required to determine its relative position to at least two adjacent components that differ from each other in two of their cartesian coordinates. In order to form a three dimensional topological mapping in an environment, a component is required to determine its relative position to at least three adjacent components that differ from each other in three of their cartesian coordinates.

In one embodiment, where one or more components of a community of sensors comprise sensors (e.g., as part of transceivers), once a sensor(s) location is determined within the topology of an enclosure, data sensed by the sensor may be monitored in view of the location. Data (e.g., signal) from any component (e.g., sensor) may be time stamped. Data from a sensor may be collated and/or analyzed. The collation and/or analysis may be performed by one or more processors. The processors may be operatively coupled to (e.g., and residing on) one or more components in the community of components. Collation and/or analysis may be performed, or directed to be performed, by and/or on one or more component comprised of a sensor and/or one or more component not comprised of a sensor (e.g., a buzzer or a light (e.g., a light emitting diode). Collation and/or analysis may be performed or directed to be performed at a location within which sensors are located and/or at a location different from that of the sensors (e.g., a remote location and/or the cloud). Analysis may utilize machine learning and/or artificial intelligence techniques (e.g., reactive, limited memory, theory of mind, and/or self-aware techniques). Monitoring data of one or more enclosure (e.g., building or room of a building) using one or more sensors (e.g., temperature, noise, power, voltage, current, radio waves, and/or gas sensors) may provide a time dependent evolution of an environment of the enclosure pertaining to the data (e.g., time dependent temperature, noise, power, voltage, current, frequency, wavelength, amplitude, and/or gas sensors) as a function of time. Evolution data may be utilized for analysis, control, maintenance, and/or prediction of the environment of an enclosure. For example, an elevated noise level at location coupled with an atypical temperature variation may indicate a malfunctioning ventilation at that location. Evolution data may be used to predict and/or prepare for future events in an enclosure (e.g., prepare an enclosure for a meeting, predict failure of a component, and/or recognize failure of a component).

In some embodiments, sensor data analysis utilizes artificial intelligence (abbreviated herein as “Al”). In some embodiments, processing sensor data comprises performing sensor data analysis. In some embodiments, the sensor data analysis comprises linear regression, least squares fit, Gaussian process regression, kernel regression, nonparametric multiplicative regression (NPMR), regression trees, local regression, semiparametric regression, isotonic regression, multivariate adaptive regression splines (MARS), logistic regression, robust regression, polynomial regression, stepwise regression, ridge regression, lasso regression, elasticnet regression, principal component analysis (PCA), singular value decomposition, fuzzy measure theory, Borel measure, Han measure, risk-neutral measure, Lebesgue measure, group method of data handling (GMDH), Naive Bayes classifiers, k-nearest neighbors algorithm (k-NN), support vector machines (SVMs), neural networks, support vector machines, classification and regression trees (CART), random forest, gradient boosting, or generalized linear model (GLM) technique.

The topology of the community may be determined with varied degrees of accuracy and/or robustness. In some embodiments, minimal number of signals are required to form a topology (e.g., without verification). In some embodiments, the number of signals forming the topology exceeds the minimum number of signals. In increase in verification signal may form a more robust topology, with greater positional accuracy of the components.

In some embodiments, the community of components determines its own topology (e.g., topology of its members). For example, the community of components (e.g., sensors) can determine a relative location of its members (e.g., using signal transmission and receipt by the components). For example, the components may utilize signal transmission and receipt to determine their relative distance from each other. A timing of the signal transmission and/or receipt may be coordinated. For example, each component may have a designated time window to transmit its signal. The designated time windows of members of the community may not overlap. The community of components may comprise stationary components.

In some embodiments, the component is configured to generate one or more signal types. The component may be configured to generate a first signal utilized for measuring relative location of the components (e.g., to form a topological mapping of the components in the enclosure).

In some embodiments, the components of the community are configured to generate time-based data. In some embodiments, the components of the community are configured to generate a random number. The random number may be generated in relation to the time-based data (e.g., the component may generate a random time to transmit its signal). The time-based data may relate to the signal transmission. The time-based data may relate to a time window (e.g., comprising start time, and end time of the time window). The random time may be chosen within a time window (e.g., that is predetermined and/or prescribed to all components in the community). The component may be configured to generate a signal comprising an identification number (abbreviated herein as “ID”). The ID may uniquely identify the component in the community. The identification number may be transmitted in radio frequency, or any other frequency disclosed herein. For example, a component may be configured to generate a start time, an end time, and/or a random time therebetween (e.g., 2.350000 s selected randomly from the time range of from 2.000000 s to 3.000000 s). When a component is disposed in an enclosure it may be turned on. Turning on the component may be manual or automatic. For example, turning on of the component may be when connecting it to the network.

In some embodiments, the component may be turned on and transmit a signal at the random time within the prescribed time window. A component may generate a random number and/or a random time designation upon being turned on or upon occurrence of a particular event. The event may comprise a detected change in a topology, e.g., entrance of a mobile component into the enclosure. The event may comprise a manual or automatic system reset).

In some embodiments, pulse-based ultra-wideband (UWB) technology (e.g., ECMA-368, or ECMA-369) is a wireless technology for transmitting large amounts of data at low power (e.g., less than about 1 millivolt (mW), 0.75 mW, 0.5 mW, or 0.25 mW) over short distances (e.g., of at most about 300 feet (′), 250′, 230′, 200′, or 150′). A UWB signal can occupy at least about 750 MHZ, 500 MHZ, or 250 MHz of bandwidth spectrum, and/or at least about 30%, 20%, or 10% of its center frequency. The UWB signal can be transmitted by one or more pulses. A component broadcasts digital signal pulses may be timed (e.g., precisely) on a carrier signal across a number of frequency channels at the same time. Information may be transmitted, e.g., by modulating the timing and/or positioning of the signal (e.g., the pulses). Signal information may be transmitted by encoding the polarity of the signal (e.g., pulse), its amplitude and/or by using orthogonal signals (e.g., pulses). The UWB signal may be a low power information transfer protocol. The UWB technology may be utilized for (e.g., indoor) location applications. The broad range of the UWB spectrum comprises low frequencies having long wavelengths, which allows UWB signals to penetrate a variety of materials, including various building fixtures (e.g., walls). The wide range of frequencies, e.g., including the low penetrating frequencies, may decrease the chance of multipath propagation errors (without wishing to be bound to theory, as some wavelengths may have a line-of-sight trajectory). UWB communication signals (e.g., pulses) may be short (e.g., of at most about 70 cm, 60 cm, or 50 cm for a pulse that is about 600 MHZ, 500 MHZ, or 400 MHz wide; or of at most about 20 cm, 23 cm, 25 cm, or 30 cm for a pulse that is has a bandwidth of about 1 GHz, 1.2 GHz, 1.3 GHZ, or 1.5 GHZ). The short communication signals (e.g., pulses) may reduce the chance that reflecting signals (e.g., pulses) will overlap with the original signal (e.g., pulse).

In some embodiments, a transitory component (e.g., an ID tag of an occupant) can include a micro-chip. The micro-chip can be a micro-location chip. The micro-chip can incorporate auto-location technology (referred to herein also as “micro-location chip”). The micro-chip may incorporate technology for automatically reporting high-resolution and/or high accuracy location information. The auto-location technology can comprise GPS, Bluetooth, or radio-wave technology. The auto-location technology can comprise electromagnetic wave (e.g., radio wave) emission and/or detection. The radio-wave technology may be any RF technology disclosed herein (e.g., high frequency, ultra-high frequency, super high frequency. The radio-wave technology may comprise UWB technology. The micro-chip may facilitate determination of its location within an accuracy of at most about 25 centimeters, 20 cm, 15 cm, 10 cm, or 5 cm. In various embodiments, the control system, sensors, transceivers, and/or antennas are configured to communicate with the micro-location chip. In some embodiments, the tag may comprise the micro-location chip. The micro-location chip may be configured to broadcast one or more signals. The signals may be omnidirectional signals. One or more component operatively coupled to the network may (e.g., each) comprise the micro-location chip. The micro-location chips (e.g., that are disposed in stationary and/or known locations) may facilitate determination of stationary components. One or more processors (e.g., of the control system) may perform an analysis of the location related signals. The relative distance, know location, and/or stationary component localization information may be aggregated. At least one of the stationary component may be disposed in a floor, ceiling, wall, and/or mullion of a building. There may be at least 1, 2, 3, 4, 5, 8, or 10 stationary component disposed in the enclosure (e.g., in the room, in the building, and/or in the facility). At least two of the stationary component may have at least of (e.g., substantially) the same X coordinate, Y coordinate, and Z coordinate (of a Cartesian coordinate system).

In some embodiments, a control system enables locating and/or tracking one or more components (e.g., comprising auto-location technology such as the micro location chip) and/or at least one user carrying such (e.g., transitory) component. The relative location between two or more such components can be determined from information relating to received transmissions, e.g., at one or more stationary components (e.g., transceivers, antennas and/or sensors). The location of the (e.g., transitory) component may comprise geo-positioning and/or geolocation. The location of the component may an analysis of electromagnetic signals emitted from the component and/or the micro-location chip. Information that can be used to determine location includes, e.g., the received signal strength, the time of arrival, the signal frequency, and/or the angle of arrival. When determining a location of the one or more components from these metrics, a localization (e.g., using trilaterations such as triangulation) module may be implemented. The localization module may comprise a calculation and/or algorithm. The localization module may account for and/or utilize the physical layout of a building. The auto-location may comprise geolocation and/or geo-positioning. Examples of location methods may be found herein and in International Patent Application Serial No. PCT/US17/31106, filed on May 4, 2017, titled, “WINDOW ANTENNAS,” which is incorporated herein by reference in its entirety.

In some embodiments, the position of the tag may be located using one or more stationary components comprising positional sensors. A sensor can be part of (e.g., included in) a transceiver. The positional sensor(s) may be disposed in the facility (e.g., enclosure as a building, or room). The positional sensor may be part of a device ensemble or separated from a device ensemble (e.g., standalone positional sensor). The positional sensor may be operatively (e.g., communicatively) coupled to a network. The network may be a network of the facility (e.g., of the building). The network may be configured to transmit communication and power. The network may be any network disclosed herein. The network may extend to a room, a floor, several rooms, several floors, the building, or several buildings of the facility. The network may operatively (e.g., to facilitate power and/or communication) couple to one or more components. For example, the network may operatively (e.g., to facilitate power and/or communication) couple to a control system (e.g., as disclosed herein), sensor(s), emitter(s), transceiver(s), antenna, radar(s), router(s), power supply, and/or to building management system (and/or its various constituents). The network may be coupled to personal computers of users (e.g., occupants) associated with the facility (e.g., employees and/or tenants). At least part of the network may be installed as the initial network of the facility, and/or disposed in an envelope structure of the facility. The network may be operatively coupled to other devices in the facility that perform operations for, or associated with, the facility (e.g., production machinery, communication machinery, and/or service machinery). The production machinery may include computers, factory related machinery, and/or any other machinery configured to produce product(s) (e.g., printers and/or dispensers). The service machinery may include food and/or beverage related machinery, hygiene related machinery (e.g., mask dispenser, and/or disinfectant dispensers). The communication machinery may include media projectors, media display, touch screens, speakers, and/or lighting (e.g., entry, exit, and/or security lighting).

In some embodiments, at least one stationary component (e.g., ensemble) includes at least one processor and/or memory. The processor may perform computing tasks (e.g., including machine learning and/or artificial intelligence related tasks). In this manner the network can allow low latency (e.g., as disclosed herein) and faster response time for applications and/or commands. In some embodiments, the network and circuitry coupled thereto may form a distributed computing environment (e.g., comprising CPU, GPU, memory, and/or storage) for application and/or service hosting to store and/or process content close to the user's mobile circuitry (e.g., cellular device, pad, or laptop).

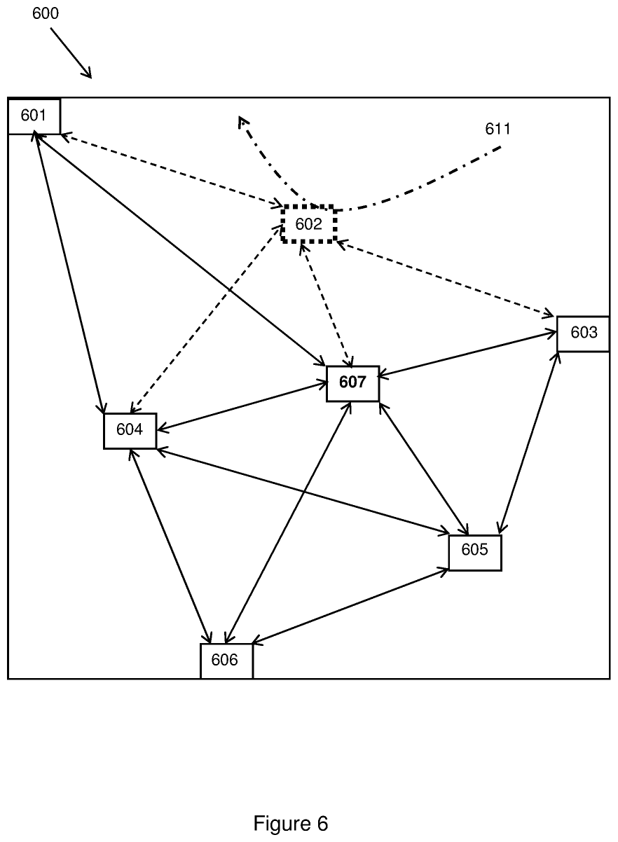

In some embodiments, if the topology of a community of components changes (e.g., via malfunction, addition, and/or removal of one or more component), a new topology may be determined. Changes in a topology of a community of components may be communicated via detection of one or more changes in signal(s) communicated by component(s) to the community. The changes in signals may include (I) a loss of signal (e.g., when a community member exits the community range and/or malfunctions), and/or (II) an introduction of a new a signal (e.g., when a mobile component enters the community range). FIG. 6 shows an example of a community of components 600 that includes stationary components 601 and 603-607, transitory component 602. The arrows other than arrow 611 designate signal directionality, while the arrow 611 designates the route of translating component 602. Dotted arrows other than 611 designate coordination related signals (e.g., commands). Solid arrows designate distance related signals for topological mapping of the components in the community.

In some embodiments, one or more changes in signal(s) comprise changes in signals generated by a motion sensor (e.g., an accelerometer) operatively coupled to the component. Operatively coupled may include associated with, or made part of, the component of a community of components. In one embodiment, each of the components of a community of components comprises its own operatively coupled motion sensor. In one embodiment, motion sensors comprise accelerometers. In one embodiment, one or more changes in a topology may be detected (e.g., and actions initiated) by one or more components of a community of components. In one embodiment, changes in a topology of components are detected (e.g., and actions initiated) by components that are not part of a community of components (e.g., by a controller disposed outside the range of the community). In one embodiment, one or more changes to a topology of components may be communicated wirelessly and/or over one or more wires.

In some embodiments, one or more controllers discussed herein monitor and/or direct (e.g., physical) alteration of the operating conditions of components, software, algorithms and/or methods described herein. Control may comprise regulate, manipulate, restrict, direct, monitor, adjust, modulate, vary, alter, restrain, check, guide, or manage. Control may comprise controlling a control variable (e.g., temperature, power, voltage, and/or current). Control can comprise real time or off-line control. A calculation utilized by the controller can be done in real time, and/or off line. A controller may be a manual or a non-manual controller. The control may be manual or automatic. A controller may be an automatic controller. A controller may operate upon request. A controller may be a programmable controller. The controller may operate according to a feedback and/or feed forward control scheme. The controller may operate according to a closed loop and/or open loop control scheme. The feed forward and/or open loop control may comprise a calculation (e.g., of a simulation). The controller may be programed. A controller may comprise a processing unit (e.g., CPU or GPU). A controller may receive an input (e.g., from at least one sensor). The controller may comprise circuitry, electrical wiring, optical wiring, socket, and/or outlet. A controller may deliver an output. A controller may comprise multiple (e.g., sub-) controllers. The controller may be a part of a control system. A control system may comprise a master controller, network controller, local controller. The local controller may be a window controller (e.g., controlling an optically switchable window), enclosure controller, or component controller. For example, a controller may be a part of a hierarchal control system (e.g., comprising a main controller that directs one or more controllers, e.g., network controllers, local (e.g., window) controllers, enclosure controllers, and/or component controllers). The local controller may control one or more devices (e.g., and be directly coupled to the devices). The local controller may be disposed proximal to the one or more devices it is controlling. For example, the local controller may control one or more components including an optically switchable device (e.g., IGU), an antenna, a sensor, a transceiver, and/or an output device (e.g., a light source, sounds source, smell source, gas source, HVAC outlet, or heater). The network controller may direct one or more window controllers, one or more enclosure controllers, one or more component controllers, or any combination thereof. For example, the network controller may be control a plurality of window controllers. The plurality of window controllers may be disposed in a portion of a facility (e.g., in a portion of a building). The portion of the facility may be a floor of a facility. For example, a network controller may be assigned to a floor. For example, a network controller may be assigned to a portion of a floor. For example, a network controller may be assigned to a portion of the window controllers disposed in the facility. For example, a network controller may be assigned to a portion of the floors of a facility. A master controller may be coupled to one or more network controllers. The network controller may be disposed in the facility. The master controller may be disposed in the facility, or external to the facility. The master controller may be disposed in the cloud. The controller may be a part of, or be operatively coupled to, a building management system. A controller may receive one or more inputs. A controller may generate one or more outputs. The controller may be a single input single output controller (SISO) or a multiple input multiple output controller (MIMO). A controller may interpret an input signal received. A controller may acquire data from the one or more components (e.g., sensors). Acquire may comprise receive or extract. The data may comprise measurement, estimation, determination, generation, or any combination thereof. A controller may comprise feedback control. A controller may comprise feed-forward control. Control may comprise on-off control, proportional control, proportional-integral (PI) control, or proportional-integral-derivative (PID) control. Control may comprise open loop control, or closed loop control. A controller may comprise closed loop control. A controller may comprise open loop control. A controller may comprise a user interface. A user interface may comprise (or operatively coupled to) a keyboard, keypad, mouse, touch screen, microphone, speech recognition package, camera, imaging system, or any combination thereof. Outputs may include a display (e.g., screen), speaker, or printer.

The methods, systems and/or the components described herein may comprise a control system. A control system can be in communication with any of the apparatuses (e.g., components comprising actuators, signal emitting devices, or sensors) described herein. Components may be of the same type or of different types (e.g., as described herein). For example, the control system may be in communication with a first component and/or with a second component. A control system may control one or more component. A control system may control one or more components of a building management system (e.g., lightening, security, and/or air conditioning system). A controller may regulate at least one (e.g., environmental) characteristic of an enclosure. A control system may regulate the enclosure environment using any component, e.g., component(s) of the building management system. For example, a control system may regulate energy supplied by a heating element and/or by a cooling element. For example, a control system may regulate velocity of an air flowing through a vent to and/or from the enclosure.

A control system may comprise a processor. A processor may be a processing unit. A controller may comprise a processing unit. A processing unit may be central. A processing unit may comprise a central processing unit (abbreviated herein as “CPU”). A processing unit may be a graphic processing unit (abbreviated herein as “GPU”). A controller(s) or control mechanisms (e.g., comprising a computer system) may be programmed to implement one or more methods of the disclosure. A processor may be programmed to implement methods of the disclosure. A controller may control at least one component of the forming systems and/or components disclosed herein. A computer system can control (e.g., direct, monitor, and/or regulate) various features of the methods, components and systems, such as, for example, control heating, cooling, lightening, and/or venting of an enclosure, or any combination thereof. A computer system can be part of, or be in communication with, any component or combination of components disclosed herein. A computer may be coupled to one or more mechanisms disclosed herein, and/or any parts thereof. For example, a computer may be coupled to one or more sensors, transceivers, valves, switches, lights, windows (e.g., IGUs), motors, pumps, optical components, or any combination thereof.

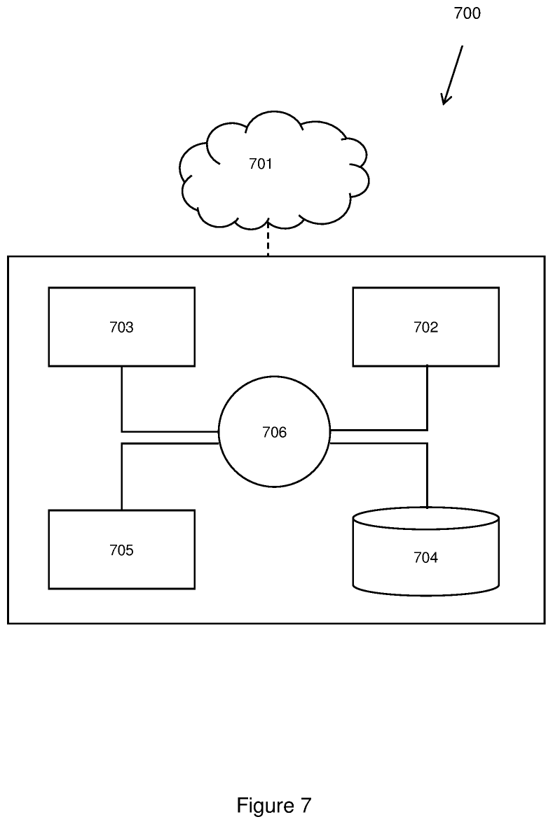

FIG. 7 illustrates an example of a processing system. A computer system can include a processing unit (e.g., 706) (also “processor,” “computer” and “computer processor” used herein). A computer system may include memory or memory location (e.g., 702) (e.g., random-access memory, read-only memory, flash memory), electronic storage unit (e.g., hard disk), communication interface (e.g., 703) (e.g., network adapter) for communicating with one or more other systems, and peripheral devices (e.g., 705), such as cache, other memory, data storage and/or electronic display adapters. In an exemplary embodiment, the memory 702, storage unit 704, interface 703, and peripheral devices 705 are in communication with the processing unit 706. The communication may comprise (e.g., be through) a communication bus (solid lines), such as a motherboard. The communication comprises wireless communication. The wires may comprise coaxial wires or twisted pair. The communication network may comprise an antenna. The storage unit can be a data storage unit (or data repository) for storing data. A computer system can be operatively coupled to a computer network (“network”) (e.g., 701) with the aid of the communication interface. The communication through the network may comprise wired or wireless communication. The network can be the Internet, an internet and/or extranet, or an intranet and/or extranet that is in communication with the Internet. The communication may be through ethernet. In some cases, the network comprises a telecommunication and/or data network. The network can include one or more computer servers, which can enable distributed computing, such as cloud computing. The one or more servers may be operatively coupled to the network. The one or more servers may be disposed in the enclosure or out of the enclosure. The one or more servers may be disposed in the facility (e.g., building) in which the enclosure is disposed or out of the facility. The one or more servers may be disposed in the facility of a company manufacturing at least a portion (e.g., component) of the enclosure (e.g., that manufactures the optically switchable window(s)). A network, in some cases with the aid of the computer system, can implement a peer-to-peer network, which may enable devices coupled to the computer system to behave as a client or a server.

In an example shown in FIG. 7, a processing unit can execute a sequence of machine readable instructions, which can be embodied in a code, program and/or software. Instructions may be stored in a memory location, such as the memory 702. Instructions can be directed to the processing unit, which can program or otherwise configure the processing unit to implement methods of the present disclosure. Examples of operations performed by the processing unit can include fetch, decode, execute, calculate, and write back. A processing unit may interpret and/or execute instructions. A processor may include a microprocessor, a data processor, a central processing unit (CPU), a graphical processing unit (GPU), a system-on-chip (SOC), a co-processor, a network processor, an application specific integrated circuit (ASIC), an application specific instruction-set processor (ASIPs), a controller, a programmable logic device (PLD), a chipset, a field programmable gate array (FPGA), or any combination thereof. A processing unit can be part of a circuit, such as an integrated circuit. One or more other components of the system 700 can be included in the circuitry.

A storage unit can store files, such as drivers, libraries and saved programs. A storage unit can store user data (e.g., user preferences and user programs). In some cases, a computer system can include one or more additional data storage units that are external to the computer system, such as located on a remote server that is in communication with the computer system, e.g., through an intranet or the Internet.

A computer system can communicate with one or more remote computer systems through a network. For instance, a computer system can communicate with a remote computer system of a user (e.g., operator). Examples of remote computer systems include personal computers (e.g., portable PC), slate or tablet PC's (e.g., Apple® iPad, Samsung® Galaxy Tab), telephones, Smart phones (e.g., Apple® iPhone, Android-enabled device, Blackberry®), or personal digital assistants. A user (e.g., client) can access a computer system via the network.

Methods as described herein can be implemented by way of machine (e.g., computer processor) executable code stored on an electronic storage location of the computer system, such as, for example, on the memory or electronic storage unit. Machine executable or machine-readable code can be provided in the form of software (e.g., an app). During use, a processor can execute the code. In some cases, code can be retrieved from the storage unit and stored on the memory for ready access by the processor. In some situations, the electronic storage unit can be precluded, and machine-executable instructions are stored on memory.

The code can be pre-compiled and/or configured for use with a machine having a processer adapted to execute the code or can be compiled during runtime. Code can be supplied in a programming language that can be selected to enable the code to execute in a pre-compiled or as-compiled fashion.

In some embodiments, a processor comprises a code. The code can be program instructions. The program instructions may cause the at least one processor (e.g., computer) to direct a control scheme (e.g., feed forward and/or feedback control loop). In some embodiments, program instructions cause the at least one processor to direct a closed loop and/or open loop control scheme. Control may be based at least in part on one or more sensor readings (e.g., sensor data). One controller may direct a plurality of operations. At least two operations may be directed by different controllers. In some embodiments, a different controller may direct at least two operations of a plurality of operations (e.g., of operations (a), (b) and (c)). In some embodiments, different controllers may direct at least two of operations of a plurality of operations (e.g., of operations (a), (b) and (c)). In some embodiments, a non-transitory computer-readable medium cause each a different computer to direct at least two operations of a plurality of operations (e.g., of operations (a), (b) and (c)). In some embodiments, different non-transitory computer-readable mediums cause each a different computer to direct at least two of operations of a plurality of operations (e.g., of operations (a), (b) and (c)). A controller and/or computer readable media may direct any of the apparatuses or components disclosed herein. A controller and/or computer readable media may direct any operations of the methods disclosed herein.

In some embodiments, the tintable window comprises an electrochromic device (referred to herein as an “EC device” (abbreviated herein as ECD), or “EC”). An EC device may comprise at least one coating that includes at least one layer. The at least one layer can comprise an electrochromic material. In some embodiments, the electrochromic material exhibits a change from one optical state to another, e.g., when an electric potential is applied across the EC device. The transition of the electrochromic layer from one optical state to another optical state can be caused, e.g., by reversible, semi-reversible, or irreversible ion insertion into the electrochromic material (e.g., by way of intercalation) and a corresponding injection of charge-balancing electrons. For example, the transition of the electrochromic layer from one optical state to another optical state can be caused, e.g., by a reversible ion insertion into the electrochromic material (e.g., by way of intercalation) and a corresponding injection of charge-balancing electrons. Reversible may be for the expected lifetime of the ECD. Semi-reversible refers to a measurable (e.g., noticeable) degradation in the reversibility of the tint of the window over one or more tinting cycles. In some instances, a fraction of the ions responsible for the optical transition is irreversibly bound up in the electrochromic material (e.g., and thus the induced (altered) tint state of the window is not reversible to its original tinting state). In various EC devices, at least some (e.g., all) of the irreversibly bound ions can be used to compensate for “blind charge” in the material (e.g., ECD).

In some implementations, suitable ions include cations. The cations may include lithium ions (Li+) and/or hydrogen ions (H+) (i.e., protons). In some implementations, other ions can be suitable. Intercalation of the cations may be into an (e.g., metal) oxide. A change in the intercalation state of the ions (e.g., cations) into the oxide may induce a visible change in a tint (e.g., color) of the oxide. For example, the oxide may transition from a colorless to a colored state. For example, intercalation of lithium ions into tungsten oxide (WO3-y (0<y≤ ˜0.3)) may cause the tungsten oxide to change from a transparent state to a colored (e.g., blue) state. EC device coatings as described herein are located within the viewable portion of the tintable window such that the tinting of the EC device coating can be used to control the optical state of the tintable window.

Examples of electrochromic devices fabricated without depositing a distinct ion conductor material can be found in U.S. patent application Ser. No. 13/462,725, filed May 2, 2012, titled “ELECTROCHROMIC DEVICES,” which is herein incorporated by reference in its entirety. In some embodiments, an EC device coating may include one or more additional layers such as one or more passive layers. Passive layers can be used to improve certain optical properties, to provide moisture, and/or to provide scratch resistance. These and/or other passive layers can serve to hermetically seal the EC stack 2820. Various layers, including transparent conducting layers, can be treated with anti-reflective and/or protective layers (e.g., oxide and/or nitride layers).

In certain embodiments, the electrochromic device is configured to (e.g., substantially) reversibly cycle between a clear state and a tinted state. Reversible may be within an expected lifetime of the ECD. The expected lifetime can be at least about 5, 10, 15, 25, 50, 75, or 100 years. The expected lifetime can be any value between the aforementioned values (e.g., from about 5 years to about 100 years, from about 5 years to about 50 years, or from about 50 years to about 100 years). A potential can be applied to the electrochromic stack such that available ions in the stack that can cause the electrochromic material to be in the tinted state reside primarily in the counter electrode when the window is in a first tint state (e.g., clear). When the potential applied to the electrochromic stack is reversed, the ions can be transported across the ion conducting layer to the electrochromic material and cause the material to enter the second tint state (e.g., tinted state).

It should be understood that the reference to a transition between a clear state and tinted state is non-limiting and suggests only one example, among many, of an electrochromic transition that may be implemented. Unless otherwise specified herein, whenever reference is made to a clear-tinted transition, the corresponding device or process encompasses other optical state transitions such as non-reflective-reflective, and/or transparent-opaque. In some embodiments, the terms “clear” and “bleached” refer to an optically neutral state, e.g., untinted, transparent and/or translucent. In some embodiments, the “color” or “tint” of an electrochromic transition is not limited to any wavelength or range of wavelengths. The choice of appropriate electrochromic material and counter electrode materials may govern the relevant optical transition (e.g., from tinted to untinted state).

In certain embodiments, at least a portion (e.g., all of) the materials making up electrochromic stack are inorganic, solid (i.e., in the solid state), or both inorganic and solid. Because various organic materials tend to degrade over time, particularly when exposed to heat and UV light as tinted building windows are, inorganic materials offer an advantage of a reliable electrochromic stack that can function for extended periods of time. In some embodiments, materials in the solid state can offer the advantage of being minimally contaminated and minimizing leakage issues, as materials in the liquid state sometimes do. One or more of the layers in the stack may contain some amount of organic material (e.g., that is measurable). The ECD or any portion thereof (e.g., one or more of the layers) may contain little or no measurable organic matter. The ECD or any portion thereof (e.g., one or more of the layers) may contain one or more liquids that may be present in little amounts. Little may be of at most about 100 ppm, 10 ppm, or 1 ppm of the ECD. Solid state material may be deposited (or otherwise formed) using one or more processes employing liquid components, such as certain processes employing sol-gels, physical vapor deposition, and/or chemical vapor deposition.

In some embodiments, an “IGU” includes two (or more) substantially transparent substrates. For example, the IGU may include two panes of glass. At least one substrate of the IGU can include an electrochromic device disposed thereon. The one or more panes of the IGU may have a separator disposed between them. An IGU can be a hermetically sealed construct, e.g., having an interior region that is isolated from the ambient environment. A “window assembly” may include an IGU. A “window assembly” may include a (e.g., stand-alone) laminate. A “window assembly” may include one or more electrical leads, e.g., for connecting the IGUs and/or laminates. The electrical leads may operatively couple (e.g., connect) one or more electrochromic devices to a voltage source, switches and the like, and may include a frame that supports the IGU or laminate. A window assembly may include a window controller, and/or components of a window controller (e.g., a dock).

In some implementations, the first and the second panes are transparent or translucent, e.g., at least to light in the visible spectrum. For example, each of the panes can be formed of a glass material. The glass material may include architectural glass, and/or shatter-resistant glass. The glass may comprise a silicon oxide (SOx). The glass may comprise a soda-lime glass or float glass. The glass may comprise at least about 75% silica (SiO₂). The glass may comprise oxides such as Na₂O, or CaO. The glass may comprise alkali or alkali-earth oxides. The glass may comprise one or more additives. The first and/or the second panes can include any material having suitable optical, electrical, thermal, and/or mechanical properties. Other materials (e.g., substrates) that can be included in the first and/or the second panes are plastic, semi-plastic and/or thermoplastic materials, for example, poly(methyl methacrylate), polystyrene, polycarbonate, allyl diglycol carbonate, SAN (styrene acrylonitrile copolymer), poly(4-methyl-1-pentene), polyester, and/or polyamide. The first and/or second pane may include mirror material (e.g., silver). In some implementations, the first and/or the second panes can be strengthened. The strengthening may include tempering, heating, and/or chemically strengthening.

In various embodiments, a network infrastructure supports a control system for one or more windows such as electrochromic (e.g., tintable) windows. The control system may comprise one or more controllers operatively coupled (e.g., directly or indirectly) to one or more windows. The enclosure comprises optically switchable devices. The optically switchable devices may include tintable windows, smart windows, and/or electrochromic windows. Optically switchable devices may comprise a liquid crystal device, or a suspended particle device. For example, a liquid crystal device and/or a suspended particle device may be implemented instead of, or in addition to, an electrochromic device.

In some embodiments, a tintable exhibits a (e.g., controllable and/or reversible) change in at least one optical property of the window, e.g., when a stimulus is applied. The stimulus can include an optical, electrical and/or magnetic stimulus. For example, the stimulus can include an applied voltage. One or more tintable windows can be used to control lighting and/or glare conditions, e.g., by regulating the transmission of solar energy propagating through them. One or more tintable windows can be used to control a temperature within a building, e.g., by regulating the transmission of solar energy propagating through them. Control of the solar energy may control heat load imposed on the interior of the facility (e.g., building). The control may be manual and/or automatic. The control may be used for maintaining one or more requested (e.g., environmental) conditions, e.g., occupant comfort. The control may include reducing energy consumption of a heating, ventilation, air conditioning and/or lighting systems. At least two of heating, ventilation, and air conditioning may be induced by separate systems. At least two of heating, ventilation, and air conditioning may be induced by one system. The heating, ventilation, and air conditioning may be induced by a single system (abbreviated herein as “HVAC). In some cases, tintable windows may be responsive to one or more environmental sensors and/or user control. Tintable windows may comprise (e.g., may be) electrochromic windows. The windows may be located in the range from the interior to the exterior of a structure (e.g., facility, e.g., building). However, this need not be the case. Tintable windows may operate using liquid crystal devices, suspended particle devices, microelectromechanical systems (MEMS) devices (such as microshutters), or any technology known now, or later developed, that is configured to control light transmission through a window. Windows with MEMS devices for tinting are described in U.S. patent application Ser. No. 14/443,353, filed May 15, 2015, titled “MULTI-PANE WINDOWS INCLUDING ELECTROCHROMIC DEVICES AND ELECTROMECHANICAL SYSTEMS DEVICES,” which is herein incorporated by reference in its entirety. In some cases, one or more tintable windows can be located within the interior of a building, e.g., between a conference room and a hallway. In some cases, one or more tintable windows can be used in automobiles, trains, aircraft, and other vehicles, e.g., in lieu of a passive and/or non-tinting window.

In some embodiments, a transitory component includes a housing. The transitory component may be a badge or tag that is carried by a person (e.g., an elderly person, children or pets such as those in need of remote tracking/monitoring) or is coupled (e.g., attached or affixed) to an object (e.g., an asset, keys, phone, medical equipment, warehouse equipment, electronic equipment). The transitory component may have a key fob-type of shape, a relatively flat polygon shape, which may include a clip for securing to objects, a watch type of shape, which may include a band for securing to a wrist, a shape for readily securing to assets that are generally stationary, or a shape that allows for ease of inserting and carrying in a clothing pocket. The housing may comprise at least one material suitable for supporting internal electronics and/or covers for enclosing the electronics. The material may comprise a metal, an allotrope of elemental carbon, a ceramic, a polymer, or a resin. The metal may be an elemental metal or a metal alloy. The material may comprise a composite material. The material may be a stiff material. The material may comprise carbon fibers or glass fibers. The material may comprise an organic polymer (e.g., carbon based polymer). The material may comprise Bakelite (polyoxybenzylmethylenglycolanhydride). The material may comprise plastic. The material may be resistant to heat, scratches, and/or organic solvents (e.g., acetone, alkanes, benzene, toluene, hydrofuran, and/or alcohols). The material may or may not be an insulator (e.g., have low electrical conductivity). The material may or may not be flammable. The material may have a tensile strength of at least about 80 mega Pascals (MPa), 85 MPa, 90 MPa, 100 MPa, 110 MPa, or 120 MPa (e.g., at ambient temperature and pressure such as at 25° C. and at 1 Atmosphere). The material may have a hardness of at least about 60 N/mm2, 80 N/mm2, 90 N/mm2, 100 N/mm2, or 110 N/mm2 (e.g., at ambient temperature and pressure such as at 25° C. and at 1 Atmosphere). The hardness may be Rockwell B, or Vickers hardness. The material may have an impact resistance of at least about 60 Kilojoule per meter (KJ/m), 65 KJ/m, 70 KJ/m, or 75 KJ/m (e.g., at ambient temperature and pressure such as at 25° C. and at 1 Atmosphere). The material may have a maximum working temperature of at least about 100° C., 150° C., 180° C., 200° C., 500° C., or 600° C. The material may have a surface resistivity of at most about 106 or, 109 ohm (e.g., at ambient temperature and pressure such as at 25° C. and at 1 Atmosphere). The material may have an electrical resistivity of at least about 2 ohm/cm, 2.5 ohm/cm, 3 ohm/cm, 3.5 ohm/cm or 4.0 ohm/cm (e.g., at ambient temperature and pressure such as at 25° C. and at 1 Atmosphere). The material may have a modulus of elasticity of at least about 60 Giga Pascals (GPa), 65 GPa, 68 GPa, 70 GPa, 75 GPa, or 80 GPa (e.g., at ambient temperature and pressure such as at 25° C. and at 1 Atmosphere). The material may or may not be transparent to electrogenic radiation. The electromagnetic radiation may comprise radiation in the ultraviolet, visible light, infrared light, or radio wave wavelength regimes.

In some embodiments, the housing includes a plurality of materials or a plurality of material classes. For example, the front and back of the housing can comprise a first material of a first class (e.g., polymer), and the rim of the housing may comprise a second material of a second (e.g., metals). The first material may be different by at least one material characteristic, from the second class of material. The material characteristic may comprise material composition, material type, electrical resistance, tensile strength, hardness, impact resistance, maximum working temperature, surface resistivity, electrical resistivity, modules of elasticity, flammability, resistance to scratches, or resistance to organic solvents. The at least one material characteristic may comprise any material characteristic disclosed herein. In some embodiments, at least a portion of the cover may comprise an external coating. The coating may comprise a visible color. The coating may comprise a powdered color.

In some embodiments, the circuitry is separated from the ambient environment by a cover. The cover may be at least partially transparent to electromagnetic waves. The covers may be formed of a material that transmits radio signal therethrough. The housing may support a port that is configured to transmit data and/or power to the internal electronic circuitry. The internal electronic circuitry may include at least one circuit board, at least one antenna, and at least one (e.g., rechargeable) battery. The battery may have a current of at least about 200 milliamperes (ma), 240 ma, 360 ma, 370 ma, 420 ma, or 500 ma. The battery may be charged multiple times, e.g., upon its (e.g., substantial) depletion. For example, the battery may be charged at least about 100 times, 250 times, 500 times, 750 times, or 1000 times. The battery may be charged a number of times between the aforementioned number of times. The antenna may be integrated with and/or separate from the circuit board(s). The battery may be charged via a battery charging circuit connected to the port and/or charged wirelessly. The port may transmit data for updating firmware on the at least one circuit board. The firmware updates may be perform at least partially wirelessly. The battery may provide power to the at least one circuit board and/or to various other internal electronic component(s). The circuit board(s) may include at least an ultra-wide band radio and/or a programmable microcontroller. The antenna(s) may include an ultra-wide band antenna and/or a Bluetooth (BLE) Low energy antenna. The BLE antenna may be connected to a Bluetooth low energy radio. The BLE antenna and/or BLE radio may be connected to the circuit board(s). The internal electronics may include an accelerometer connected to the circuit board(s). The transitory component (e.g., the identification tag) may be three dimensional. The three-dimensional transitory component may be sized (e.g., height, width, thickness) to minimize its overall dimensions. The overall dimensions (e.g., fundamental length scale) may be the minimum required to contain and support the internal components. The overall dimensions may be configured to allow for external access to the port (e.g., to form electrical connection). The transitory component may have surfaces that taper on one of its sides, e.g., to minimize the overall dimensions, ease usage, ease storage, and/or increase aesthetic appeal, of the transitory component.

In some embodiments, the tag is configured to signal its operational status. For example, the tag is configured to signal its energetic capabilities (e.g., battery status). The signaling may comprise visual (e.g., using light), tactile (e.g., using vibrations), and/or audial (e.g., using sound such as beeping) signaling. The light may be in the visible spectrum. The visible light may be emitted by an LED light. The visible light may be a signaling light. The signaling light may signal operational states of the tag including: normal operation (e.g., indicated by green or blue light), insufficient power (e.g., depletion of battery power. E.g., indicated by yellow or orange light), and/or malfunction of the tag (e.g., indicated by red light). An intensity of the visible light may fluctuate. The fluctuation may or may not depend on operational states. The light intensity fluctuations may be (e.g., substantially) the same for at least two of the operational states. The light intensity fluctuations may be different for at least two of the operational states. The fluctuations may be between light and no-light, intense and less intense light, or any combination thereof. The frequency of the fluctuation may depend on the operational state. The signal intensity (e.g., light intensity, vibrational intensity, or sound intensity) may fluctuate between high intensity and low intensity. The low intensity may include no intensity. The fluctuation may resemble a top hat function. Transition between the low intensity to high intensity (e.g., ramp up) may be gradual (e.g., linear, logarithmic, or exponential). Transition between the high intensity to low intensity (e.g., ramp down) may be gradual (e.g., linear, logarithmic, or exponential). The ramp up and down curves may follow the same trend (e.g., may be of opposing trends, and have the same absolute value). The ramp up and down curves may follow different trends (e.g., may be of opposing trends, and have different absolute values). For example, the ramp up and down may vary in time and/or in function. At least one of the signaling pattern (e.g., of the light intensity fluctuations, vibrations, or sounds) may resemble an animate (e.g., human) breathing pattern. The tag may comprise a (e.g., manual) on/off switch.

In some embodiments, a cover of the tag housing is configured to facilitate visible light transmission. The cover may have a hole disposed above a light emitter disposed in the tag interior. For example, the cover hole may be aligned with an LED disposed on the PCB board inside the tag. The cover may be made of a material that facilitates light to come through. For example, the material may be of a light color (e.g., white, pastel, transparent, or at least partially transparent), e.g., a light hue (e.g., yellow). The material may be a polymeric material. The cover may be of a width that facilitates sufficient visible light transmission detectable by an average human eye. For example, the cover may have a width of at most 0.5 millimeters (mm), 1 mm, 1.5 mm, or 2 mm. The cover material may have a width between any of the aforementioned widths. The thickness of the cover may be configured to allow penetration of visible light therethrough. The tag (e.g., cover and/or framing) may comprise one or more holes configured to facilitate sound emission, e.g., such that sounds generated by a sound emitter in the tag (e.g., buzzer or loudspeaker) may be auditable by an average human ear.

The tag may comprise a housing having at least one framing portion and at least one cover portion. The framing and/or cover portion may provide structure to the tag housing. The framing and/or cover portion may provide structure to the tag interior. The framing and/or cover portion may be a chassis (e.g., framework) for internal elements of the tag. For example, the framing and/or cover portion may be configured to support the circuitry, antenna, transceiver, emitters (e.g., sound and/or light), connector, wiring, and/or battery. The chassis may comprise any material disclosed herein (e.g., metal or plastic). The chassis may include a surface treatment (e.g., chemical or physical surface treatment). The surface treatment may comprise anodizing, abrading, polishing, or coating the surface. Coating may comprise a protective coat and/or color. coating may comprise powder coating or wet coating.

In some embodiments, an external portion of the tag housing comprise symmetry. In some embodiments, an internal portion of the tag may be devoid of symmetry. The external tag housing tag may comprise mirror and/or rotational (e.g., C₂) symmetry. The tag may comprise at least one axis of symmetry. For example, a portion of the external tag housing may be symmetric along its length and/or along its width. The axis may be symmetrically tarped along its length. Tapering of the tag towards one of its ends may be symmetric. The two opposing sides of the tag may be mirror images of each other and/or relate to each other along a (e.g., C₂) rotational axis and/or a mirror plane. The frontal and backward covers may be non-symmetric. For example, the frontal cover may contain a hole configured to facilitate transmission of an indicator light (e.g., LED light), and the back cover may be devoid of such hole. The frontal and backward covers may be symmetric. For example, the frontal cover may be made of a material configured to facilitate transmission of an indicator light (e.g., LED light) and be devoid of a hole, and the back cover may be made of the same material and also be devoid of such hole. The front and the back of the tag may relate to each other using mirror symmetry. A portion of the external framing may be symmetric, while another portion of the tag may be non-symmetric (e.g., entry of the connector (e.g., USB) may be disposed non-symmetrically along a face of the framing portion.

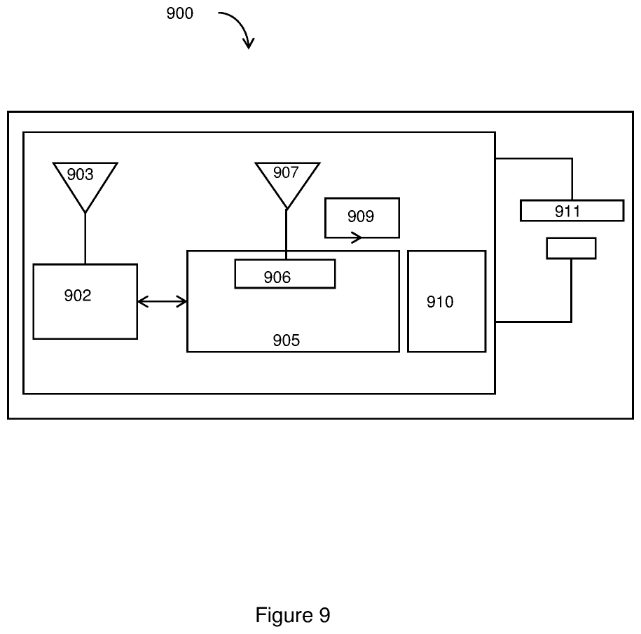

FIG. 9 shows an example of internal components for a transitory component 900, which may be a badge or tag that is carried by a person and/or an object. The internal components may include an ultra-wideband (UWB) radio 902 (e.g., a Decawave™ integrated circuit UWB wireless transceiver (DWM1000) or other types of UWB wireless transceivers), and UWB antenna 903 in communication with the radio 902. The radio 902 may be coupled to a programmable microcontroller 905 (e.g., ARM M4™ microcontroller and/or other type of programmable microcontroller, e.g., as disclosed herein). The microcontroller 905 may include a short range wireless radio 906 (e.g., a Bluetooth™ Low Energy (BLE) radio and/or other short range wireless radios). The short range wireless radio 906 may be in communication with an antenna 907. The tag 900 may also include an accelerometer 909. The accelerometer 909 may sense movement of the tag 900 and communicate such information to the microcontroller 905. A charging circuit 910 may be included in the tag 900. The charging circuit 910 may operatively engage the microcontroller 905 and a rechargeable battery 911, which may be charged via a wired port or wirelessly. The locating a tracking of a transitory component (e.g., element 900) may be accomplished as discussed herein relative to at least FIG. 1, element 102b, and FIG. 6, elements 602 that moves in path 611.

In some embodiments, the transitory component and/or stationary component comprises an accelerometer. The accelerometer may sense movement of the housing in which it is located (e.g., hosing of the tag or housing of the stationary component). Movement sensing by the accelerometer may trigger transmission of a single (e.g., beacon) from the housing in which the accelerometer is disposed (e.g., signaling by the tag or signaling by the stationary component). Usage of the accelerometer may reduce energy expenditure by the tag and/or accelerometer, e.g., by restricting location tracking of the moved housing to times in which the housing (e.g., of the tag or of the housing) has moved or is moving. Usage of the accelerometer of the stationary component may trigger location of the stationary component (e.g., by requesting a traveler to locate the stationary component and/or by initiating an automatic location of the stationary component, e.g., as disclosed herein).

In some embodiments, the transitory component (e.g., tag) has a housing comprising a frame and one or more covers. The frame may be disposed in a rim of the tag. The covers may comprise a frontal cover and a real cover disposed opposite to the frontal cover. The framing portion may comprise one or more sub-portions. The framing portion may be made from one piece of material. The framing portion and/or cover may by generated by three-dimensional printing, machining, and/or injection molding. The cover and framing portion may be of the same type of material or of different material types. For example, the framing portion may comprise metal, and the cover(s) may comprise a polymer. The cover may be configured to nest on, or snap to, the framing portion. The cover may be affixed to the framing portion by at least one adhesive and/or at least one fastener (e.g., screw). A surface of the framing portion and the cover may flush to form one surface. The surface of the framing and the cover may have a height difference (e.g., by one of them being proud or recessed) by at most about 0.02 millimeters (mm), 0.06 mm, 0.09 mm, 0.12 mm, or 0.15 mm. The framing portion may comprise curvature. The framing portion may devoid of external sharp corners (e.g., susceptible to damage). The framing portion may be configured to withstand scratching, dropping from at least about 5 feet (′), 6′, 7′, or 10′. The framing portion may be configured to withstand scratching, dropping from at least about 1 meter (m), 1.5 m, 2 m, 2.5 m, 3 m, or 5 m.

In some embodiments, a framing of the tag and a cover of the tag are coupled using an adhesive. The adhesive may comprise a film. The film may be configured for adhesive contact on opposing sides (e.g., a double sided tape). The film may comprise a porous material (e.g., a foam). The film may comprise a polymer (e.g., an acrylic polymer). The adhesive may be configured for bonding materials in the electronics industry (e.g., 3M™ VHB™ Tape such as 5980). The adhesive may be sensitive to pressure. The adhesive may have a tensile strength of at least about 400 kPa, 500 Kilo Pascal (kPa), 550 kPa, 600 kPa, or 700 kPa. The adhesive may have density of at least about 550 Kg/m³, 600 Kg/m³, 700 Kg/m³, or 800 Kg/m³.

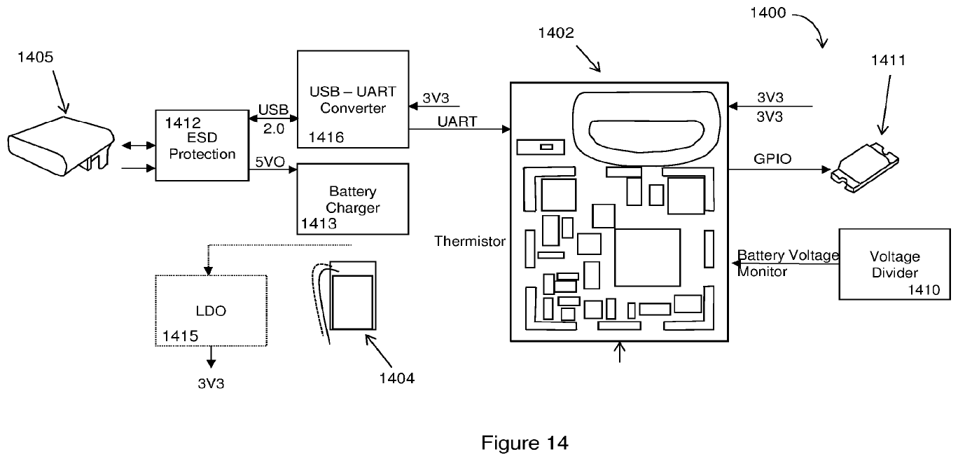

FIG. 14 illustrates an example of a portion of the internal components for a transitory component 1400, which may be a badge or tag that is carried by a person and/or object. The internal components may include an ultra-wideband (UWB) radio 1402 (e.g., a Decawave™ integrated circuit UWB wireless transceiver (DWM1000) or other types of UWB wireless transceivers), a port 1405 (e.g., a USB, USB-C or other type of port for transferring data and/or electric power), a rechargeable battery 1404 (e.g., a lithium ion, lithium polymer and/or other type of rechargeable battery), a voltage divider 1410, and/or a light emitting diode (LED) 1411. The port 1405 may include an electrostatic discharge (ESD) protection module 1412 and connect through this module to a battery charger 1413, which connects to the rechargeable battery 1404 for charging. The rechargeable battery may also connect with a low drop out (LDO) regulator 1415. The port 1405 may connect with the circuit board of the radio 1402 via a USB to universal asynchronous receiver-transmitter (UART) converter 1416. The LED 1411 and the voltage divider 1410 may connect with and be controlled by the circuit board of the radio 1402. The circuitry comprises a thermistor, and a general purpose input/output (GPIO) integrated circuit connectivity (e.g., pin), hat may be controlled by a software. The voltages depicted in the example shown in FIG. 14 are 3.3 Volts (designated as 3V3), or 5.0 Volts (designated as 5V0).

In some embodiments an stationary component may include internal components (a device ensemble) that include at least one radio (e.g., an ultra-wide band and/or a Bluetooth radio such as a low energy radio), at least one antenna (e.g., an ultra-wide band and/or a Bluetooth antenna such as a low energy antenna), an accelerometer, a power/charging circuit, at least one transceiver circuit, at least one sensor circuit (e.g., for detecting one or more conditions around the stationary component), and/or a network adapter/connection (e.g., a backbone communications chip). A backbone communications chip may comprise Ethernet (which may include power-over-Ethernet), Wi-Fi, Multi-media over Coax Alliance (MoCA) or power line (G.hn) technology. A backbone communications chip may be configured to enable at least a fourth or a fifth generation communication protocol. The sensor can be part of the transceiver. A processor (e.g., CPU or GPU) can be included in a standalone chip or be integrated with a backbone communication chip (e.g., inside a G.hn chip). Power line (G.hn) technology may be configured to send and/or receive data encoded in accordance with one or more protocols which include (i) a next generation home networking protocol (abbreviated herein as “G.hn” protocol), (ii) communications technology that transmits digital information over power lines that traditionally used to (e.g., only) deliver electrical power, and/or (iii) hardware devices designed for communication and transfer of data (e.g., Ethernet, USB and Wi-Fi) through electrical wiring of a building. The G.hn interface may be configured to provide bidirectional communications (e.g., in a G.hn communications protocol) between the two devices. One or more controllers may include an Ethernet interface coupled to a second connector. The Ethernet interface may be configured to provide bidirectional communications in an Ethernet protocol between a second external device and the device. The one or more controllers (and the network) may be configured to translate communications between the G.hn and Ethernet protocols. The data transfer protocols may facilitate data transmission rates of at least 1 Gigabits per second (Gbit/s), 2 Gbit/s, 3 Gbit/s, 4 Gbit/s, or 5 Gbit/s. The data transfer protocol may operate over telephone wiring, coaxial cables, power lines (e.g., home wiring), and/or (e.g., plastic) optical fiber. The G.hn protocol may comprise signal frequency for data signals from about 2 to about 200 MHz (e.g., that complies with the G.hn protocol), and/or may allow the transmission of data over any wire medium (e.g., as disclosed herein). Data rates within the G.hn protocol may be in the range of from about 100 megabit/sec up to about 1.7 Gb/sec. A network bus may utilize the G.hn protocol. The interface for coupling to the network bus may be a G.hn interface (also referred to as a G.hn controller).

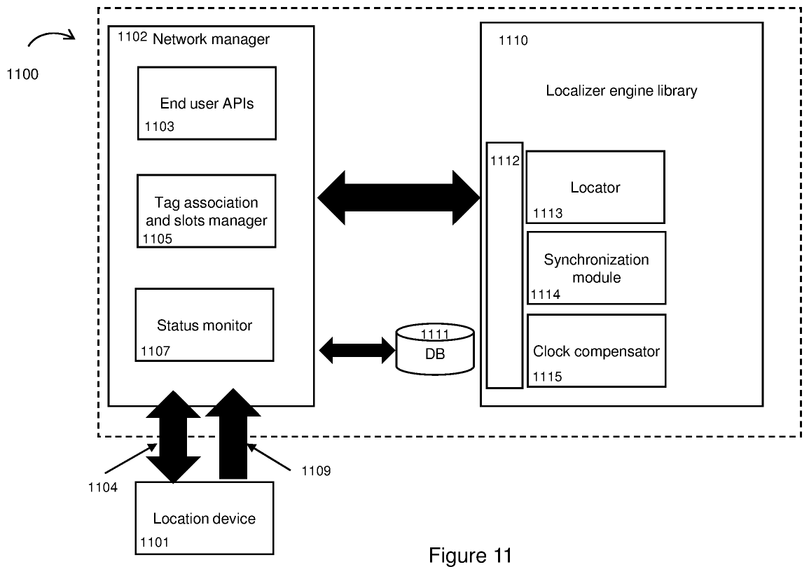

In some embodiments, the transitory component comprises a controller. The controller may be a microcontroller. The controller may be configure to operatively (e.g., communicatively) coupled to the network of a facility. The controller of the tag may be configure to (i) perform, request, and/or initiate firmware (e.g., Bootloader and DFU) update, (ii) communications (e.g., Bluetooth (BLE) communication), (ii) power management (e.g., charging indication and/or battery management), (iii) motion detection (e.g., using an accelerometer internal to the tag), signal (e.g., UWB) configuration, (iv) tag application layer, (v) signal command module (e.g., very low frequency (VLF) command module), (vi) signal (e.g., UWB) transmission and/or receipt (TX/RX) scheduling, (vii) signal (e.g., UWB) Media Access Layer (MAC) implementation, and/or (viii) clock synchronization and/or calibration. The controller may be configured to perform at least a portion of the operations delineated in FIG. 11. In some embodiments, very low frequency comprise radio frequencies (RF) in the range of from about 3 Kilo Hertz (KHz) to about 30 KHz. The VLF electromagnetic waves (e.g., myriameter band or myriameter waves) may correspond to wavelengths from about 100 kilometers (km) to about 10 km.

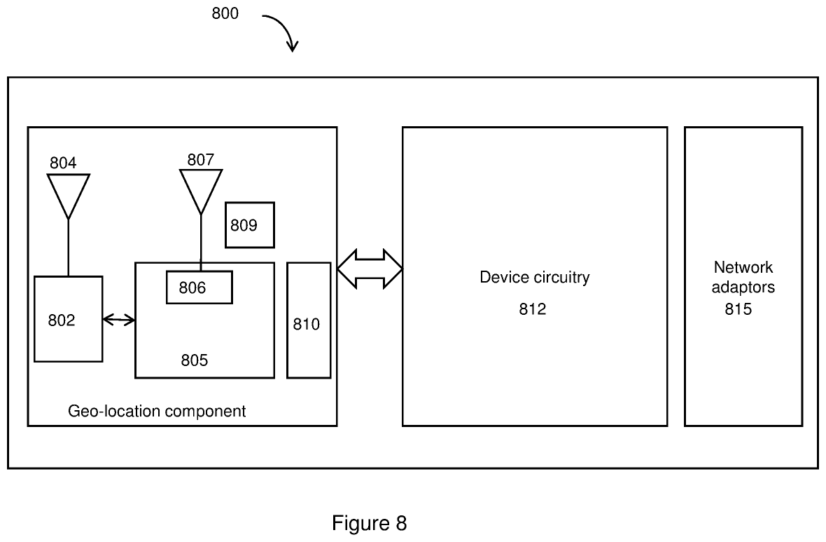

FIG. 8 shows an example of internal components for a stationary component 800. Such stationary components 800 may be similar to those discussed herein relative to, e.g., FIGS. 1, and 3-6. Examples of stationary components, their control, and their networking, can be found in U.S. Provisional Patent Application Ser. No. 63/079,851, filed Sep. 17, 2020, titled, “DEVICE ENSEMBLES AND COEXISTENCE MANAGEMENT OF DEVICES,” the disclosure of which is incorporated herein by reference in its entirety. The internal components may include an UWB radio 802, and UWB antenna 804 in communication with the radio 802. The radio may operatively engage a programmable circuitry (e.g., microcontroller) 805 (e.g., ARM M4™ microcontroller and/or other type of programmable microcontroller). The microcontroller 805 may include a short range wireless radio 806 (e.g., a Bluetooth™ Low Energy (BLE) radio and/or other short range wireless radios). The short range wireless radio 806 may be in communication with an antenna 807. The stationary component 800 may also include an accelerometer 809. The accelerometer 809 may sense movement of the stationary component 800 and communicate such information to the microcontroller 805. A power/charging circuit 810 may be included in the stationary component 800. The power/charging circuit 810 may operatively engage the microcontroller 805 and a source of power (e.g., battery and/or power supply from a facility in which the stationary component 800 is located). The internal components of the stationary component 800 may include sensor circuits 812 that detect various conditions around the stationary component 800. The internal components of the stationary component 800 may include a network adapter/connection 815 (e.g., wireless connection, power-over-Ethernet (POE) connection, Multimedia over Coax Alliance (MoCA), power line (e.g., G.hn) technology, and/or other type of network communication connection).

In some embodiments, a location of a transitory component (e.g., tag) may be determined based at least in part on communication with a plurality of stationary components, e.g., disposed in a facility. The determination of the location of the transitory component may employ (i) a time of flight method (referred to herein as ToF), (ii) a time difference of arrival method (referred to herein as TDoA), or (iv) a hybrid combination of the time of flight and the time difference of arrival methods. The positions for the stationary components may be known (e.g., using a traveler and/or self-location of the stationary components, e.g., as disclosed herein). The stationary components may be at least three, or at least four, stationary components, depending on the methodology utilized. For example, the ToF and/or TDoA methodologies can utilize at least three stationary components (e.g., for two dimensional localization, e.g., localization on a plane defined by the three stationary components), and the TDoA method can utilize at least three stationary components (e.g., for three dimensional localization, e.g., localization on a volume defined by the four stationary components). In some embodiments, the more stationary components are utilized, the greater the location accuracy is achieved.

In some embodiments, a TDoA method is utilized for location of a transitory component (e.g., tag). The TDoA method utilizes a single sided (e.g., one way) ranging that may refer to transmission from the transitory component (e.g., tag) to the stationary components. In the TDoA methodology, the transitory component can send out a signal (also called a blink) that may be received by the stationary components. A time delay for each receipt of the signal is determined. Based at least in part on the time delay information, combined with the known positions of the stationary components, the position of the transitory component is determined. In the single sided (e.g., one way) ranging methodology, a transitory component can send out a signal (also called a blink, or a beacon) at time to, which signal comprises a time stamp information corresponding to. The tag transmitted signal may be received by three or more stationary components. The tag transmitted signal may be received by four stationary components. The tag transmitted signal can be received by the stationary components (e.g., four stationary components) at times t₁, t₂, t₃, or t₄, respectively. At least two of the times at which the signal is received by the stationary components may be different, e.g., when those at least two stationary components are disposed at different distances from the tag. At least two of the times at which the signal is received by the stationary components may be (e.g., substantially) the same, e.g., when those at least two stationary components are disposed at the (e.g., substantially) same distance from the tag. After receipt of the signal by the stationary components, its information that corresponds to t₀ is compared to the time at which the signal was received by the stationary component (e.g., t₁, t₂, t₃, or t₄). The time delay between signal sending time to is compared for each stationary component with the signal receipt time (e.g., t₁, t₂, t₃, or t₄). The time delay between signal sending time and signal receipt time (e.g., t₁-t₀, t₂-t₀, t₃-t₀, or t₄-t₀) is converted to the distance traveled by the signal from the tag to each of the stationary components (e.g., using the speed of light and/or trilaterations), and thus the location of the tag can be determined with respect to the stationary components. Using actual location of the stationary components (e.g., as corroborated by a traveler and/or by the self-locating procedure, e.g., as disclosed herein), an actual location of the tag at time to can be determined. The location determination may be performed at a processor of an stationary component. In some embodiments, the timing related information is transmitted (e.g., by the stationary components and/or by the tag) to the network operatively coupled to the stationary components; and the tag location determination is performed by the network (e.g., in the cloud, by a processor, and/or by a controller operatively coupled to the network).

In some embodiments, the localization of the transitory component utilizes an asynchronized TDoA methodology (ATDoA), e.g., that does not require clock synchronization. The TDoA methodology may require at least three, fourth, or five stationary components to interact (e.g., receive signal) from the transitory component. The ATDoA can be used with or without other methodologies (e.g., ToF and TDoA).

In some embodiments, a ToF method is utilized for location of a transitory component (e.g., tag). The ToF method utilizes double sided (e.g., two way, or back-and-forth) ranging. Double sided ranging may refer to a first transmission from a transitory component that is received by the stationary components (e.g., in a similar manner to the one sided signal transmission of the TDoA methodology disclosed herein), followed by a second transmission in the reverse direction from the stationary components that is received by the transitory component. In the double sided ranging methodology, a forward signal sending and a back signal sending is employed between the tag and the stationary components.

In the forward sending portion of the ToF methodology: a transitory component can send out a signal (also called a blink, or a beacon) at time to, which signal comprises a time stamp information corresponding to. The tag transmitted signal may be received by the stationary components (e.g., three stationary components) at times t₁, t₂, or t₃ respectively. At least two of the times of signal receipt by the stationary components may be different, e.g., when these at least two stationary components are disposed at different distances from the tag. At least two of the times of signal receipt by the stationary components may be (e.g., substantially) the same, e.g., when these at least two stationary components are disposed at the (e.g., substantially) same distance from the tag. After receipt of the signal by the stationary components, its information that corresponds to t₀ is compared to the time at which the signal was received by the stationary component (e.g., t₁, t₂, or t₃). The time delay between signal sending time to is compared for each stationary component with the signal receipt time (e.g., t₁, t₂, or t₃). The time delay (e.g., time difference) between signal sending time and signal receipt time (e.g., t₁−t₀, t₂−t₀, or t₃−t₀) is converted to the distance traveled by the signal from the tag to the stationary component (e.g., using the speed of light and/or trilateration), and thus location of the stationary component can be estimated with respect to the stationary components. Using actual location of the stationary components (e.g., as corroborated by a traveler and/or by the self-locating procedure, e.g., as disclosed herein), an actual location of the tag (e.g., at time to) can constitute the first location estimate. To increase accuracy of the location estimate, a back sending of signal is followed.

In the back sending portion of the ToF methodology: the (e.g., three) stationary components each can send out a signal (also called a blink, or a beacon) at times (e.g., t₅, t₆, or t₇, respectively) which each of the three signals comprises a time stamp information corresponding t₅, t₆, or t₇, respectively. The stationary component transmitted signal may be received by the transitory component at time t₈, t₉, or t₁₀, respectively. At least two of the times of signal sending by the stationary components may be different or (e.g., substantially) the same. At least two of the times or signal receipt by the tag may be different or (e.g., substantially) the same. After receipt of at least one stationary component signal by the tag (e.g., at time t₈, t₉, or t₁₀, respectively), its information that corresponds to the signal sending time (e.g., t₅, t₆, or t₇, respectively) is compared to the time at which the signal was received by the tag. The time delay (e.g., time difference) between stationary component signal sending time and tag signal receipt time (e.g., t₈-t₅, t₉-t₆, or t₁₀-t₇) is converted to the distance traveled by the signal from the stationary component to the tag (e.g., using the speed of light and/or trilateration), and thus location of the tag can be estimated with respect to the stationary components to form a second estimate. Using actual location of the stationary components (e.g., as corroborated by a traveler and/or by the self-locating procedure, e.g., as disclosed herein), an actual location of the tag can constitute the second location estimate. The first estimate can be compared to the second estimate to increase the accuracy of determining the location of the tag, e.g., if the tag did not move substantially between the back and forth communication between the stationary components and tag. For example, if the beacons are sent in a velocity and delay that is orders of magnitude faster than the tag (e.g., human) movement. In some embodiments, the timing related information is transmitted (e.g., by the stationary components and/or by the tag) to the network operatively coupled to the stationary components; and the tag location determination is performed by the network (e.g., in the cloud, by a processor, and/or by a controller operatively coupled to the network).

In some embodiments, a combination between the ToF and TDoA methodologies is employed. The ToF methodology can be more accurate than the TDoA methodology in determining the location of the transitory component. In the ToF, no clock synchronization is required across the participating stationary components. The transitory component may require increased power to perform the ToF methodology as compared to the TDoA methodology (e.g., due to the greater signal communication, and optional calculations). This may leave to higher battery of the tag when utilizing the ToF (e.g., two way) methodology as compared to the TDoA (e.g., one way) methodology. The TDoA may require clock synchronization between all participating stationary components. Since the signals are short timed, the clock synchronization may be required to be precise (e.g., to a fraction of the signal short time). The TDoA may facilitate determining more tags simultaneously as compared to the number of tags the ToF method can locate simultaneously. For example, using the TDoA methodology, the tag does not need to wait for a reply (e.g., back signal) arriving from the participating stationary components. The TDoA methodology may be employed, while supplementing with (e.g., occasional and/or prescheduled) ToF measurements. Supplementation of the ToF methodology may be to facilitate (i) clock synchronization among participating stationary components, and/or (ii) accuracy verification of determining tag location. In some embodiments, the timing related information is transmitted (e.g., by the stationary components and/or by the tag) to the network operatively coupled to the stationary components; and the tag location determination is performed by the network (e.g., in the cloud, by a processor, and/or by a controller operatively coupled to the network). The communication between the network and the stationary components can be mono or bidirectional (e.g., wired and/or wireless) communication.

The localization analysis (e.g., using ToF, TDoA, and/or ATDoA) may utilized one or more computations. The computation(s) may comprise a least squares estimation that is based at least in part on a range (e.g., between the stationary component(s) and transitory component). The computations may require solving nonlinear equation(s). The computation may utilize direct computational method, constrained iterative computational method, and/or iterative descent computational method. The Iterative descent computational method may comprise steepest descent, Newton, or Gauss-Newton, computational method. The constrained iterative computational method may comprise Kalmar filtering (e.g., linear quadratic estimation). Kalmar filtering may afford smoother position estimates as compared to the other computational methods. Some of the computational methods disclosed herein are heavier (e.g., require more computational time and/or power) than others.

In some embodiments, the localization system by be a real-time localization system, e.g., that provides localization of the transitory time in real time. The location may be an absolute location or a relative location (e.g., relative to the enclosure and/or the stationary components). The computational methodologies may comprise generation of a first set of estimates of current state variables, along with their uncertainties, based at least in part on a first set of measurements. Once an outcome of the next (e.g., second) set of measurements is observed, the first estimates are updated. The update by utilize a weighted average (e.g., with more weight being given to estimates with higher certainty). The computational methodology may be recursive. The computational method may be performed in real time. The computational method may utilize (e.g., only) present input measurements, previously calculated state, and/or its uncertainty (e.g., compiled as an uncertainty matrix). The computation methodology may assumes that the errors are of a Gaussian nature. The primary sources may be assumed to follow an independent gaussian random processes, e.g., with a zero mean. The dynamic systems may be linear. When the process and/or measurement covariances are known, the computational method may generate a good linear estimator (e.g., in the minimum mean-square-error sense).

In some embodiments, the localization methodology can locate a plurality of moving tags (e.g., in the same enclosure and/or simultaneously). For example, the localization methodology can locate at least about 2, 10, 20, 25, 50, 75, 100, 500, or 1000 tags disposed in the same enclosure (e.g., simultaneously). The localization methodology can locate any number of tags between the aforementioned values.

In some embodiments, determination of the time differentiation between signal sending and its receipt depends on an accurate account of time. The accurate account may be at least one tenth, one hundredth, or one thousandth of a length of the signal time span (e.g., beacon or blip time span), or more accurate. The accurate account may be to at most about one microsecond, nanosecond, picosecond, or femtosecond resolution. The accurate account may be to at most about ten microsecond, nanosecond, picosecond, or femtosecond resolution. The accurate account may be to at most about hundred microsecond, nanosecond, picosecond, or femtosecond resolution. The clock systems for each of the location participating stationary components, may be synchronized.

In some embodiments, the stationary component comprises a clock. The clock may comprise a crystal oscillator.

The stationary component may comprise circuitry that uses mechanical resonance of a vibrating crystal (e.g., of piezoelectric material) to create an electrical signal with a constant frequency. This frequency may be used to keep track of time, e.g., to provide a stable clock signal for digital integrated circuits, and/or to stabilize frequencies for transmitters and receivers (e.g., transceivers). The crystal may be a quartz crystal, however other piezoelectric materials including polycrystalline ceramics may be used. The crystal oscillator may consider slight change in shape of a quartz crystal under an electric field (e.g., electrostriction or inverse piezoelectricity). A voltage applied to an electrode on the crystal may indicate it to change shape; when the voltage is removed, the crystal may generate a small voltage as it elastically returns to its original shape. The crystal may oscillates at a stable resonant frequency. The crystal frequency may have a frequency of at least about 10 kilohertz (KHz), 25 KHz, 50 KHz, 75 KHz, 100 KHz, 250 KHz, 500 KHz, 750 KHz, or 1000 kHz. The crystal frequency may have a frequency of at least about 100 megahertz (MHZ), 250 MHz, 500 MHZ, 750 MHz, or 1000 (MHz). Once a crystal is adjusted to a frequency, it should maintain that frequency with high stability. However, over time, the frequency of the clock may drift (e.g., due to environmental influences). The oscillation of the clocks may drift. The oscillation of various clocks may be misaligned. The ToA methodology may be utilized to synchronize the clocks. The synchronization may include accounting for (I) clock domain (e.g., when the clock in each stationary component starts), (II) clock offset (e.g., clock frequency of crystal oscillations for the clock in each stationary component being slightly different), and/or (III) clock drift (e.g., changes in ambient temperature and/or aging of the clock crystals may alter its vibrational frequency). In some embodiments the sensors and/or transceivers may be operatively coupled (e.g., wired and/or wirelessly) to one clock, e.g., that is calibrated and/or synchronized (e.g., with Greenwich clock time of the Royal Observatory in Greenwich, London time).

In some embodiments, a transitory component (e.g., tag) sends out a blink, which is received by the participating stationary components. Each of the participating stationary components may detect the time of arrival of a signal. The difference in the arrival time of the signal at each of the participating stationary components (e.g., along with the known location of each of the at least three stationary components) can be utilized to determine the location of the transitory component. A hybrid usage of time of flight (TOF) and time difference of arrival (TDoA) may be employed for determining the location of the transitory component when the transitory component is in communication with the participating stationary components (e.g., whose positions may be known). The ToF method, as described herein, may be employed to determine the position of a transitory component and/or be utilized to synchronize the clocks in the stationary components. The TDoA method may be used to (e.g., repeatedly) determine the position of the transitory component over a (e.g., predetermined) time interval and/or over a (e.g., predetermined) number of transitory components location determinations. After the time interval and/or over a number of transitory components location determinations, as the case may be, the TOF method can (e.g., again) be employed to determine the position of the transitory component and/or synchronize the clocks among the stationary components. The TDoA method can be employed as discussed herein (e.g., above). The hybrid use of the two methods of transitory component location may provide clock synchronization while minimizing power usage by the tag (e.g., thus maximizing the time needed between battery charges of the transitory component battery). For example, the TDoA methodology requires one sided signal transmission between the transitory and stationary components, while the ToF methodology requires a back and forth (e.g., two sided) signal transmission. TDoA method may allow for faster determination of a position of a transitory component, as compared to the ToF method. The TDoA method may allow for tracking of more transitory components in a community than ToF, e.g., since no reply signal from stationary components is used. The TDoA method may use less computational resources on a transitory component than the ToF method, which may allow for a battery on the transitory component to last longer between charges.

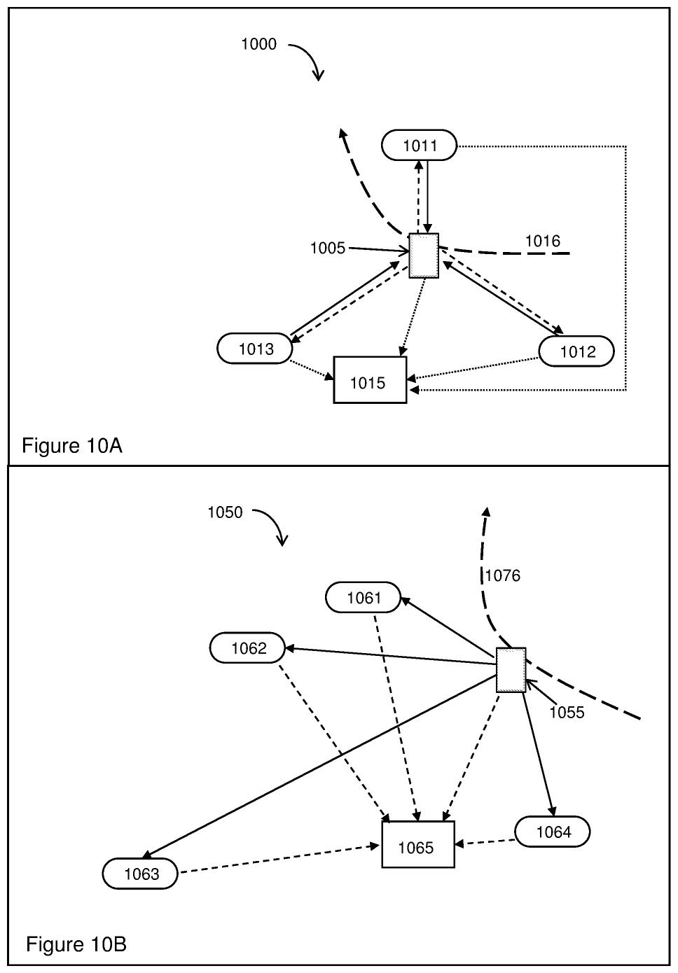

FIG. 10A shows an example of a setup 1000 for determining location of a transitory component 1005 methodology. The location determination is based at least in part on communication of the transitory component with multiple stationary components (e.g., element 800 in FIG. 8). This method may employ three stationary components or more stationary components. In the example shown in FIG. 10A, the method employs three stationary components 1011, 1012 and 1013. The position of the stationary components 1011-1013 may be known. Double sided ranging (e.g., two way, or back and forth, or round trip) ranging methodology associated with ToF may be employed. For double sided ranging, a transitory component 1005 sends out a signal (also called a blink, or a beacon) at time to, which signal comprises a time stamp information of to, and which signal is received by the stationary components 1011, 1012, and 1013 at times t₁, t₂, and t₃, respectively. On receipt of the signal by each of the stationary components, the time information for to is compared to the time at which the signal arrived at (e.g., is received by) the stationary components. The time delay between signal sending and signal receipt (e.g., t₁−t₀, t₂−t₀, and t₃−t₀) is converted to the distance traveled between the transitory component 1005 and each of the stationary components, and is estimated in a first estimate. This communication is designated in FIG. 10A as broken arrow lines between tag 1005 and stationary components 1011-1013 respectively. Reinforcement of the first estimated distance is performed by a return signal in which each of the stationary components 1011-1013 sends its signal with its time stamp corresponding to times t₅, t₆, and t₇, respectively. The signals are received by the transitory component at times t₈, t₉, and t₁₀, and the distance is then calculated based at least in part on the time differences (e.g., t₈-t₅, t₉-t₆, and t₁₀-t₇) to generate a second distance estimate. The return communication between the stationary components and the tag is designated in FIG. 10A by solid (e.g., non-broken) arrow lines. The transitory nature of the tag is designated by line 1016 designating the traveling path of tag 1005. The stationary components and tag may communicate (e.g., the timing information) to the network and/or any component coupled thereto such as a control system 1015. The two estimates are compared to find the distance between the transitory components and the stationary components. The communication between the stationary components and the tags, and the control system 1015 is designated in FIG. 10A by dotted arrow lines. The comparison can be done on an stationary component, or the network, or on another component coupled to the network.

FIG. 10B shows an example of a setup 1050 for determining location of a transitory component 1055 methodology. The location determination is based at least in part on communication of the transitory component with multiple stationary components (e.g., element 800 in FIG. 8). This method may employ at least three (e.g., four) stationary components or more stationary components. In the example shown in FIG. 10B, the method employs four stationary components 1061, 1062, 1063, and 1064. The position of the stationary components 1061-1064 may be known. Single sided ranging (e.g., one way) ranging methodology associated with TDoA may be employed. For single sided ranging, a transitory component 1055 sends out a signal (also called a blink, or a beacon) at time to, which signal comprises a time stamp information of to, and which signal is received by the stationary components 1061, 1062, 1063, and 1064 at times t₁, t₂, t₃, and t₄, respectively. On receipt of the signal by each of the stationary components, the time information for to is compared to the time at which the signal arrived at (e.g., is received by) the stationary components. The time delay between signal sending and signal receipt (e.g., t₁−t₀, t₂−t₀, t₃−t₀, and t₄−t₀) is converted to the distance traveled between the transitory component 1055 and each of the stationary components, which distance is determined. This communication is designated in FIG. 10B as solid (e.g., non-broken) arrow lines between tag 1055 and stationary components 1061-1064, respectively. The transitory nature of the tag is designated by line 1076 designating the traveling path of tag 1055. The stationary components and tag may communicate (e.g., the timing information) to the network and/or any component coupled thereto such as a control system 1065. The communication between the stationary components, the tags, and the control system 1065 is designated in FIG. 10B by broken arrow lines.

FIGS. 10A and 10B show an example of two methods (ToF and TDoA) for determining location of a transitory component based on communication with stationary components. A hybrid use of the two methods may be employed for determining and/or tracking location of the transitory component, e.g., when there are at least three (e.g., four) stationary components in the community of stationary components. The ToF method, e.g., as described herein, may be employed (e.g., occasionally) to determine the position of a transitory component and/or synchronize clocks of the stationary components. The TDoA method may be used to repeatedly and/or routinely determine the position of the transitory component over a predetermined time interval and/or over a predetermined number of transitory component location determinations. After the predetermined time interval and/or over a predetermined number of transitory component location determinations, as the case may be, the ToF method is (e.g., again) be employed, e.g., to determine the position of the transitory component and/or to synchronize the clocks in the stationary components. The TDoA method can (e.g., then) be employed as discussed herein. The hybrid use of the two methods of transitory component location may provide clock synchronization and/or accurate location determination, while maximizing efficiency of power usage (e.g., while maximizing a time needed between charges of the transitory component battery).

In some embodiments, the tag may be assigned to an individual (a person). The personal tag may send signals at a higher frequency as compared to the asset tag. The tag (e.g., personal tag) may send a signal every most about 5 seconds (sec), 10 sec, 12 sec, 15 sec, 20 sec, 30 sec, 1 minute (min), 5 min, or 10 min. The frequency of signal sending may depend on detection of any movement by an accelerator component of the tag, battery life, at least one characteristic of the carrier (e.g., carrier type), and/or localization method utilized (e.g., TDoA or ToF).

In some embodiments, signal transmission frequency by the transitory component may depend on at least one characteristic of its carrier. The at least one characteristics may comprise movement rate and/or carrier type. For example, the carrier of the transitory component may be a person or an asset. A tag carried by the person may transmit signals at a higher frequency than a tag attached to an asset. For example, the carrier of the transitory component may be a laptop, a desktop, or a heavy manufacturing machinery. The laptop may be more mobile than the desktop that may be more mobile than the heavy manufacturing machinery. The signaling frequency of a tag attached to the laptop may signal in higher frequency than the tag attached to the desktop that may signal at a higher frequency than the tag attached to the heavy manufacturing machinery. The asset tracking tags may be assigned to transmit signal (e.g., blink or beacon) with a frequency (e.g., less often) that depend on (I) the length of the super time frame and/or (II) at least one characteristic of their carrier. For example, the asset tracking tags may be assigned to transmit signal (e.g., blink or beacon) with a lower frequency (e.g., less often) as compared to (I) the length of the super time frame and/or (II) the signal transmission frequency of the transitory frequency that are assigned to non-assets (e.g., that are assigned to personnel). Accordingly, the location of each asset tracking tag may be determined with a lower frequency (less often). The power expenditure of the tag may depend on the signaling frequency and/or processing performed by the tag circuitry. For example, the battery usage may be reduced for the asset tracking tags as compared to the personnel tags as the asset tags blink at a lower frequency than the personnel tags. The lower frequency for determining the position of each asset tracking tag may be acceptable since the objects to which the asset tracking tags have been attached generally do not move very often as compared to the assigned blinking frequency of their associated tags.

In some embodiment, a lowering of the energy expenditure of the tag is requested. For example, when the tag comprises a battery, it may be advantageous to expand the battery life, and/or expand the time between recharging the battery (when the battery is rechargeable). The battery may have at least about 12 hours, 1 day (d), 5 d, 7 d, 14 d, 1 month (M), 3M, 6M, 9M or 12M battery life and/or time between recharge. The energy expenditure of the tag may depend on signals sent, signals received, and/or processing (e.g., performed) performed by the tag (e.g., circuitry thereof). The energy expenditure of the tag may be lowered when a feedback mechanism is utilized for sending the signal in which (i) the tag enters a sleep mode (e.g., standby mode) during a period in which no signal is transmitted when no movement of the tag is detected by an accelerator embedded in the tag, and (ii) the tag exits the sleep mode when a movement of the tag is detected by the accelerator. The tag controller may facilitate entry into, and exit from, the sleep (e.g., standby) mode. There may be a difference in energy expenditure between signal sending mode of the tag, and signal receipt mode of the tag. For example, the signal sending mode may require at least about 5 times (*), 10*, 50*, 100*, or 500* less energy (e.g., power) as compared to the signal receipt mode. The signal seeing mode may require less energy (e.g., be more energy efficient) than the signal receipt mode. The signal receipt mode may require signal processing, e.g., by the tag circuitry (e.g., by the controller and/or processor that is part of the tag). A methodology that requires only one way communication in which the tag sends signals to stationary components such as TDoA, may expand the life of the tag as compared to using a methodology that requires two way communication in which the tag sends and receives signals, such as ToF. A hybrid methodology that minimizes usage of two way communication (e.g., minimizes usage of ToF methodology) may be able to minimize energy expenditure by the tag while providing its accurate localization.

In some embodiments, a software and hardware that forms part of a location framework for a facility includes wired and/or wireless communication that connects devices (e.g., stationary components, transitory components and other devices, e.g., as disclosed herein) via one or more networks together to one or more central computing and/or control systems (e.g., central computers, cloud based computer systems). A location device (e.g., stationary component and/or transitory component) may communicate (e.g., via wired (e.g., ethernet) and/or wireless (e.g., UWB) transmission) with a network manager, which may include end user application programming interfaces (APIs). The communication may include a bidirectional control channel relating to location network management functions, with data relating to, for example, network association of transitory components, stationary component role management, status monitoring (e.g., low battery level in a component), and/or coordinate system mapping. A wireless location device may communicate with the network manager via a one-way data channel that originates from a location device. The data channel may transmit location related data (e.g., ToF and/or TDoA related data) of the transitory components to the network manager. The network manager may communicate with a localizer engine library and/or a database, which may store data relating to stationary components and/or transitory components (e.g., location data for each transitory component). The localizer engine library may include, for example a localizer application programming interface (API), a location computational scheme, a synchronization module, and/or a clock synchronization module (e.g., to account for time drifts). The synchronization module synchronizes the clock and provides an output to the at least one stationary component. For example, the stationary component may record that 1 second (s) in the clock (e.g., in a clock of a stationary component) equals 1.00001 s in the tag clock, thus the stationary component clock and the transitory component (e.g., tag) clock have a synchronization factor of 1.000001. The time compensation module utilizes the synchronization factor for removing the clock misalignment in the transmission or receipt (TX/RX) signal. For example, when a signal is received from a tag, which signal has a timestamp 1000001 generated by the tag according to the tag clock, the time compensation module would convert the tag to 1000000 to align with the stationary component time. The synchronization module and/or time compensation module may be required when the clock is integrated in a fixed hardware that cannot be altered, and/or when the clocks cannot be otherwise physically synchronized with the coordinator clock. The clock synchronization may be achieve by utilizing one or more modules (e.g., software), e.g., as disclosed herein.

FIG. 11 shows an example of software and hardware that forms part of a location framework 1100, which may include wired and wireless communication that connects devices (e.g., stationary components, transitory components and other devices) via one or more networks together to one or more central computing systems (e.g., central computers, cloud based computer systems). Examples of determination of the number of stationary components and transitory components that make up each community, location of the stationary components and transitory components, locations of transitory components relative to each other for further analysis (e.g., tracing locations of transitory components in a grid and/or use of transitory component locations for contact tracing), the analysis, and control and networking of the components, can be found in U.S. Provisional Patent Application Ser. No. 63/115,886, filed Nov. 19, 2020, titled, “IDENTIFYING AND REDUCING HEALTH RISKS IN A FACILITY,” which is incorporated by reference herein in its entirety. Examples of components (e.g., devices or device ensembles), their location and data analysis, their control and networking, can be found in U.S. Provisional Patent Application Ser. No. 63/033,474, filed Jun. 2, 2020, titled, “ENVIRONMENTAL ADJUSTMENT USING ARTIFICIAL INTELLIGENCE.” which is incorporated by reference herein in its entirety.

As shown in FIG. 11, a location device 1101 (e.g., stationary component and/or transitory component) communicates (e.g., via wired (e.g., Ethernet, G.hn, MoCA) and/or wireless (e.g., UWB) transmission) with a network manager 1102, which may include end user application programming interfaces (APIs) 1103. The communication may include a bidirectional control channel 1104 relating to location network management functions, with data relating to, for example, network association of transitory components 1105, status monitoring 1107 (e.g., alerting for low battery level in a component), and/or coordinate system mapping. A wireless location device 1101 may communicate with the network manager 1102 via a one-way data channel 1109 that originates from a location device 1101. The data channel 1109 may transmit ToF and/or TDoA data of the transitory components to the network manager 1102. The network manager 1102 may communicate with a localizer engine library 1110 and/or a database 1111, which stores data relating to stationary components and/or transitory components (e.g., location and/or timing data for the transitory components and/or stationary components). The localizer engine library 1110 may include, for example a localizer API 1112, a location computational scheme (e.g., calculation) 1113, a synchronization module 1114, and/or a drift compensation and clock error compensation module 1115.

In some embodiments, transitory component (e.g., tag) location and tracking is achieved. A tag may transmit a wireless (e.g., UWB) signal, which may be detected by one or more stationary components in a facility. Upon detection of a tag by one or more stationary components, the tag may be joined to a network and assigned to a community. The location of the tag may be determined and/or tracked. The locating of the tag may be accomplished employing ToF and/or TDoA. Tracking of tag locations may be transmitted to a network manager and/or may be stored in a database. A determination may be made as to whether the location of the tag relative to other tags is requested. If not, the locating and tracking of the tag may continue. If so, identification of tags meeting requested criteria (e.g., time frame in question and/or location near a particular other tag) may be identified. Upon identifying tags meeting the requested criteria, the length of time within the determined relative locations of the tag to the identified tags may be calculated. For example, the control system may notify a user and/or tag holder in case the tag approached another tag at a distance below a minimum distance threshold, for a period of time exceeding the minimum time threshold. Such application may be utilized for social distance tracing. Examples for usage of components (e.g., devices and/or tags) for contact tracing, related analysis, and component control and networking, can be found in U.S. Provisional Patent Application Ser. No. 63/115,886, filed Nov. 19, 2020, entitled, “IDENTIFYING AND REDUCING HEALTH RISKS IN A FACILITY,” which is incorporated by reference herein in its entirety.

In some embodiments, a Building Information Modeling (BIM) (e.g., Revit file) is utilized at least in part to determine and/or estimate location of the stationary components in a facility. Examples of components (e.g., devices or device ensembles), their location (e.g., using a BIM file) and data analysis, their control and networking, can be found in U.S. Provisional Patent Application Ser. No. 63/033,474, filed Jun. 2, 2020, titled, “ENVIRONMENTAL ADJUSTMENT USING ARTIFICIAL INTELLIGENCE,” which is incorporated by reference herein in its entirety.

In some embodiments, the transitory component (e.g., tag) is linked to a carrier. The tag may be linked (e.g., in a database) to an identity of its carrier that can be animate or inanimate (e.g., person or asset). When carried by the carrier the tag may identify location of the carrier at a particular time. For example, a tag having a first identification is linked to a person having a certain name. For example, a tag having a second identification is linked to a machine or household item having a certain name and/or Serial Number.

In some embodiments, locating a plurality of stationary components (e.g., FIG. 3-FIG. 5, FIG. 8) in a facility (e.g., an office building, a home, a private house, an apartment, a single family house, or a townhouse) is achieved. At least three of the stationary components of the plurality of components may be initiated (e.g., visual, audible, and/or other notice to a user that an input of a location of one of the at least three stationary components is requested). The at least three of the stationary components may be at separate locations in the facility. For each of the at least three stationary components, a procedure may be performed to determine each of their position in the facility. The procedure may include (i) activating an application that is configured to receive an input, (ii) requesting input of a location for each of the at least three stationary components, and (iii) storing the location for each of the at least three stationary components in a database, after receiving the location input (e.g., from a user or from the component). The application configured to receive the input may operate on a graphical user interface (GUI) of a device. The device may be a mobile device (e.g., a cellular phone, a laptop computer, a pad, or an identification tag). The device may be other than a mobile device (e.g., a stationary device such as a desktop computer). The application configured to receive the input may comprise non-transitory computer readable program instructions (e.g., embedded in one or more media), which may be read by one or more processors, which in turn may comprise circuitry. The program instructions may comprise logic. The input for the location of each of the at least three stationary components may comprise a (e.g., digital and virtual) map of at least a portion of the facility. The map of at least a portion of the facility may be displayed to a user through a GUI of the device running the application. The map may comprise a building information modelling (BIM) file, an architectural plan, a building blueprint file, a three-dimensional building file, and/or a plan view of a layout of rooms in a building. The application may request input from the user to indicate (e.g., via the GUI) where on the map the stationary component is located, which may be repeated for (e.g., all of) the at least three stationary components. The application may request input from the user to indicate a name of a room where the stationary component is located, which may be repeated for (e.g., all of) the at least three stationary components. The database for storing the location of the at least three stationary components may be located within the facility. The database for storing the location of the at least three stationary components may be located in another location (e.g., cloud storage) separate from the facility. The database for storing the location of the at least three stationary components may be a storage component of a mobile device. Positions of other stationary components (e.g., other than the at least three stationary components whose positions may be determined at least in part by user inputs) may be determined at least in part by determining relative distances of the other stationary components relative to the at least three stationary components (e.g., see FIGS. 10A and 10B and related disclosure). The determination of positions of the other stationary components may comprise (i) transmitting a signal from the at least three stationary components of known location, which signal is received by the other stationary components of unknown location, and (ii) using the signal to calculate relative positions between the at least three stationary components and the other stationary components. Determination of the relative distances of the other stationary components to the at least three stationary components may comprise determining the relative distances of the other stationary components relative to (e.g., each of) the at least three stationary components. An automatic detection of a stationary component being moved after its position has been located in the facility may be achieved. For example, the component may comprise an accelerometer that may be sensitive to movement, e.g., and alert the control system that the component has been moved (e.g., a position of the component has been altered). For example, detection of the stationary component being moved may occur when distances to other of the plurality of stationary devices change. Upon detection of a move of the stationary component, an application may initiate relative distance measurement to detect the component that has been moved, while utilizing at least a portion of the localized components. Upon detection of a move of the stationary component, an application may request that a user input a new location for the component that has been relocated. Upon detection of a move of the relocated component, an application may suggest, based on new calculated distances to others of the localized stationary components, a new determined location of the relocated component. A user may confirm the newly determined location (e.g., upon request by the control system, e.g., through the application (e.g., having the GUI). Upon receiving a new position for the relocated component, the new position may be stored in a database.

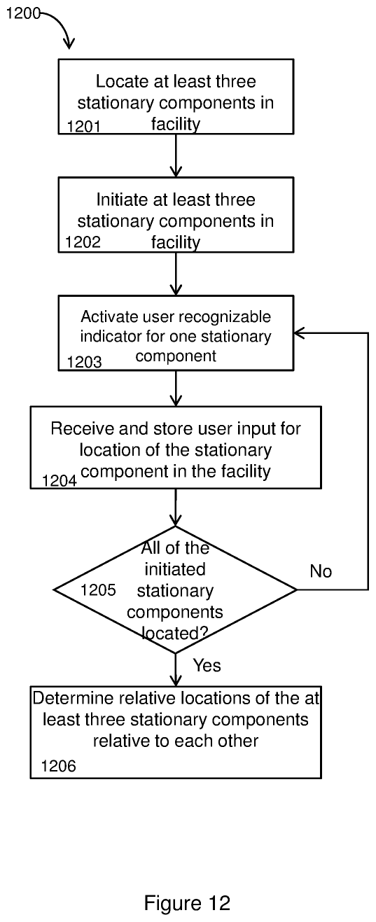

FIG. 12 shows a flow chart 1200 illustrating an example of locating a plurality (e.g., three or more) of stationary components in a facility in operation 1201. At least three stationary components, at separate locations of the facility, are initiated at operation 1202. A user (e.g., human) recognizable indicator for one stationary component is activated in operation 1203. A user input for location in the facility of the stationary component with the activated indicator is received and stored in operation 1204. If all of the at least three initiated stationary components have not activated an indicator and received user input for location in the facility in operation 1205, then processing for the next of the at least three initiated stationary components, and operations 1203 to 1204, is carried out. If all of the at least three initiated stationary component have been located via user input, as inquired in operation 1205, then relative locations of the at least three stationary components, relative to each other, are determined in operation 1206.

In some embodiments, locating a transitory component (e.g., FIG. 6, FIG. 9, FIG. 14) in a facility (e.g., an office building, a home, a private house, an apartment, a single family house, or a townhouse) is achieved. A signal may be transmitted from the transitory component to a plurality of stationary components, for at least three of which the position of the stationary components has been determined at least in part by considering an external input. A location of the transitory component may be determined based at least in part on the positions of at least three of the plurality of stationary components. The location of the transitory component may be communicated to a user. The communication of the location of the transitory component may be to a mobile device (e.g., a cellular phone, a laptop computer, a pad or an identification tag). The application configured to communicate the location of the transitory component may comprise non-transitory computer readable program instructions, which may be read by one or more processors (e.g., comprising circuitry). The location of the transitory component may be communicated to the user, e.g., through a GUI that indicates a location on a virtual map of at least a portion of the facility. The map may comprise a building information modelling (BIM) file, an architectural plan, a building blueprint file, a three-dimensional building file, and/or a plan view of a layout of rooms in a building. The location of the transitory component may be communicated to the user, e.g., through a GUI that indicates a name and/or functionality of a room in the facility. The signal transmitted from the transitory component to the plurality of stationary components may be periodic (e.g., once every second, once every 5 seconds, once every 10 seconds, once every 30 seconds, once every minute, once every two minutes, once every 5 minutes, once every 10 minutes). The signal transmitted from the transitory component to the plurality of stationary components may be non-periodic (e.g., sporadic), may be predetermined, or may not be predetermined. The signal transmitted from the transitory component to the plurality of stationary components may depend at least in part to any relocation of a component, to an emergency situation, or to a malfunction and/or revival of a component. The emergency situation may relate to health and/or safety of: the facility and/or of the user. The signal transmitted from the transitory component to the plurality of stationary components may relate to a predetermined event. The predetermined event may be of an event type. The predetermined event may be based on a schedule. The predetermined event may be triggered by a trigger. The trigger may be preprogrammed and/or determined by the user. The interval of the period between signal transmission may be predetermined. The interval of the period between signal transmission may vary based at least in part on a user input. A user may enable and/or disable (e.g., real-time) localization of the transitory component. When disabled, a transitory component may cease transmitting a signal. When disabled, a transitory component may reduce a frequency of transmitting a signal (e.g., once per hour, once per day, once per week, or other intervals). The user input for enable and/or disable may be (e.g., via a GUI) in communication with the transitory component.

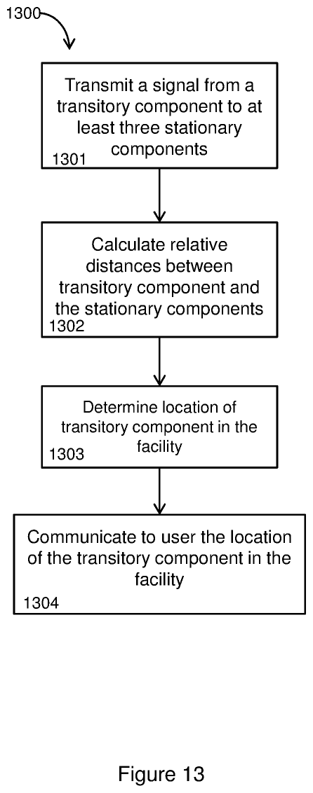

FIG. 13 shows a flow chart 1300 illustrating an example of locating a transitory component in a facility. A signal is transmitted from the transitory component to at least three stationary components is depicted in block 1301, where the positions of the at least three stationary components have been determined at least in part by considering an external input. Relative distances between the transitory component and each of the at least three stationary components is calculated in block 1302 (e.g., using techniques discussed relative to FIG. 10A and/or FIG. 10B). The location of the transitory component in the facility is determined in block 1303. A location of the transitory component in the facility is communicated to the user in block 1304.

In some embodiments, a user utilizes the control system to control one or more devices coupled to the network. The one or more devices may include a refrigerator, a stove, an oven, a microwave oven, a pizza oven, a convection oven, a humidifier, a de-humidifier, a toaster, an air fryer, a vacuum cleaner system, a washing machine, a clothes dryer, a dish washer, a food processor, a media player, a media screen, a radio, a music player, a heater, a cooler, a ventilator, lighting, a safety related device, a health related device (e.g., heart rate monitor, or sugar level monitor), a tintable window, an automatic door, an electrical fence, an automatic gate, and/or a heating, ventilation and air conditioning (HVAC) system. The user may establish one or more rules for control of the one or more devices. The rules may be hierarchical rules, e.g., giving deference to an emergency situation and/or to particular (e.g., preselected) personnel. The emergency situation may relate to health and/or safety of: the facility and/or of the user. The control may relate to a predetermined event. The predetermined event may be of an event type. The predetermined event may be based on a schedule. The predetermined event may be triggered by a trigger. The trigger may be preprogrammed and/or determined by the user. The control may comprise a logic (e.g., a conditional logic such as an “if then” type logic). The control may be facilitated though an application (e.g., having a GUI). The application may or may not be the same as the one for component location. The application may reside on a processor (e.g., on a mobile or stationary circuitry). Localization of the components may facilitate control of the one or more devices in the facility. For example, the component(s) may comprise a temperature sensor that provides feedback to the HVAC system (e.g., thorough the control system). For example, the component(s) may comprise a gas (e.g., VOC, radon (Rn), hydrogen sulfide, ammonia, nitrogen oxide, nitrous oxide(s), O₂, or CO₂) sensor that provides feedback to the ventilation system and/or automatic system configured to open or close window(s) and/or door(s) (e.g., thorough the control system). For example, the component(s) may comprise a sounds sensor that provides feedback (e.g., thorough the control system) to the sound system (e.g., white noise engine and/or music player). For example, the component(s) may comprise a particulate matter sensor that provides feedback (e.g., thorough the control system) to the ventilation system and/or automatic system configured to open or close window(s) and/or door(s). For example, the components may comprise visible light detectors that provide feedback (e.g., thorough the control system) to the lighting and/or tintable glass systems. The control system may receive the sensed signals and control the one or more devices (respectively), e.g., using a feedback control scheme and/or rules. The control system may consider a heuristic. The control system may comprise, or be operatively coupled to, artificial intelligence engine (e.g., comprising machine learning). For example, the artificial intelligence engine may consider preference of user(s) of the facility, e.g., through their various selections and/or inputs.

While preferred embodiments of the present invention have been shown, and described herein, it will be obvious to those skilled in the art that such embodiments are provided by way of example only. It is not intended that the invention be limited by the specific examples provided within the specification. While the invention has been described with reference to the afore-mentioned specification, the descriptions and illustrations of the embodiments herein are not meant to be construed in a limiting sense. Numerous variations, changes, and substitutions will now occur to those skilled in the art without departing from the invention. Furthermore, it shall be understood that all aspects of the invention are not limited to the specific depictions, configurations, or relative proportions set forth herein which depend upon a variety of conditions and variables. It should be understood that various alternatives to the embodiments of the invention described herein might be employed in practicing the invention. It is therefore contemplated that the invention shall also cover any such alternatives, modifications, variations, or equivalents. It is intended that the following claims define the scope of the invention and that methods and structures within the scope of these claims and their equivalents be covered thereby.

1-133. (canceled)

134. A system for locating a transitory component in a facility, comprising:
a plurality of stationary components of the facility configured to receive a signal transmitted from the transitory component, and
a network operatively coupled to the plurality of stationary components, which wherein the network is configured to;
communicate with at least three of the stationary components of the plurality of stationary components,
facilitate determination of positions of the at least three stationary components based at least in part on considering an external input, and
facilitate location of the transitory component based at least in part on the positions of the plurality of stationary components.

135. The system of claim 134, wherein the network is configured to facilitate determination of the positions at least in part by being configured to transmit communication related to the positions, and the network is configured to facilitate location of the transitory component at least in part by being configured to transmit communication related to the location.

136. The system of claim 134, wherein the network is configured to facilitate transmission of geo-location signals.

137. (canceled)

138. The system of claim 136, wherein the geo-location signal comprises ultra-wideband and/or a wireless personal area network technology.

139. (canceled)

140. The system of claim 138, wherein the wireless personal area network technology comprises a range of at most about 100 meters, a transmit power of from about 10 Watts to about 100 Watts, a frequency range of from about 2400 Mega Hertz (MHz) to about 2483.5 Mega Hertz, a data rate of from about 0.125 Megabits per second to about 2 Megabits per second (Mb/s), or any combination thereof.

141-181. (canceled)

182. The system of claim 134, wherein the transitory component comprises a cellular phone, an identification tag, a laptop, and/or a pad.

183. The system of claim 134, wherein the stationary components are operatively coupled to a network configured to facilitate control of at least one device of the facility different than the stationary components, the at least one device including (i) a service device, (ii) a safety device, (iii) a security device, and/or (iv) a health device.

184. The system of claim 183, wherein the service device comprises a refrigerator, a stove an oven, a microwave oven, a toaster an air fryer, a vacuum cleaner system, a washing machine, a dish washer, a clothes dryer, a food processor, a media player, a media screen, a radio, a music player, a heater, a cooler, a ventilator, lighting, a tintable window, an automatic door, or a heating, ventilation and air conditioning (HVAC) system.

185. The system of claim 183, wherein the service device is configured to adjust an environment of the facility.

186. The system of claim 183, wherein the safety device comprises an alarm, an announcement system, alarm lighting, a sensor, a door, a window, or a lock.

187. The system of claim 183, wherein the health device comprises a glucose monitor, a heart rate monitor, a blood pressure monitor, a temperature sensor, an infrared sensor, an ultraviolet sensor or a visual sensor.

188. The system of claim 183, wherein the service device includes a processor, or a media display that comprises a television screen or a computer monitor.

189. The system of claim 134, wherein:
the plurality of stationary components includes at least three stational components are configured to be initiated, and
the network is operatively coupled to an application configured to receive input, and is further configured for communicating with the at least three stationary components to facilitate performing a procedure including:
activating the application configured to receive input,
requesting input of a location of each of the at least three stationary components, and
storing the location for each of the at least three stationary components in a database, which network is disposed at least in part in the facility.

190. The system of claim 189, wherein:
the application is configured to receive the input comprises a user interface, and
the user interface comprises a map of at least a portion of the facility.

191. The system of claim 190, wherein the map comprises a building information modelling (BIM) file, an architectural plan, a home blueprint file, a three-dimensional home file, a plan view of a room layout of a home, or a combination thereof.

192. The system of claim 189, wherein the facility comprises a home, a private house, an apartment in a multi-unit apartment building, a single-family house, a condominium, or a townhouse.

193. The system of claim 189, wherein the at least three stationary components configured to be initiated are attached to, or embedded in, one or more fixtures of the facility.

194. The system of claim 189, wherein a stationary component of the plurality of stationary components comprises a device ensemble.

195. The system of claim 134, wherein the network comprises a home control system.

196. The system of claim 134, further comprising a controller configured to execute, or direct execution of, the determination and the location.
